(19) United States
(12) Patent Application Publication
(10) Pub. No.: US 2026/0282494 A1
(43) Pub. Date: Sep. 17, 2026

(54) SEMICONDUCTOR DEVICE MANUFACTURING METHOD AND SEMICONDUCTOR DEVICE

(71) Applicant: KABUSHIKI KAISHA TOSHIBA, Kawasaki-shi (JP)

(72) Inventor: Tatsuo SHIMIZU, Shinagawa Tokyo (JP)

(73) Assignee: KABUSHIKI KAISHA TOSHIBA, Kawasaki-shi (JP)

(21) Appl. No.: 19/535,944

(22) Filed: Feb. 10, 2026

(30) Foreign Application Priority Data
Mar. 12, 2025 (JP) 2025-039721

(51) Int. Cl. H10D 64/27; H10D 30/47; H10D 62/832

(52) U.S. Cl. CPC H10D 64/513; H10D 30/475; H10D 62/8325

(57) ABSTRACT

A semiconductor device manufacturing method of embodiments includes: forming a mask material, which has openings repeatedly arranged, on a surface of a nitride semiconductor layer including a first n-type region; performing first processing for implanting at least one substance selected from H, He, and electrons into a first region of the nitride semiconductor layer by using the mask material as a mask; performing a first ion implantation for implanting p-type impurities into a second region shallower than the first region by using the mask material as a mask; performing a first heat treatment; performing a second ion implantation for implanting nitrogen (N) into the nitride semiconductor layer by using the mask material as a mask; and performing a second heat treatment.

### CROSS-REFERENCE TO RELATED APPLICATION

This application is based upon and claims the benefit of priority from Japanese Patent Application No. 2025-039721, filed on Mar. 12, 2025, the entire contents of which are incorporated herein by reference.

### FIELD

Embodiments described herein relate generally to a semiconductor device manufacturing method and a semiconductor device.

### BACKGROUND

Semiconductor elements such as transistors are used in circuits such as switching power supply circuits and inverter circuits. These semiconductor elements are required to have high breakdown voltage and low on-resistance. There is a trade-off relationship between breakdown voltage and on-resistance, which is determined by the element material. By using a nitride semiconductor, such as gallium nitride or aluminum gallium nitride, as an element material of a semiconductor element, the trade-off relationship determined by the element material can be improved.

As a structure to achieve both high breakdown voltage and low on-resistance in vertical transistors, there is a superjunction structure (hereinafter, also referred to as “SJ structure”). In the SJ structure, a p-type region and an n-type region are arranged alternately in the lateral direction. A depletion layer extending in the lateral direction in the p-type region and the n-type region reduces the electric field strength in the semiconductor, thereby realizing a high breakdown voltage of the transistor. At the same time, by increasing the concentration of the impurity region, it is possible to realize the low on-resistance of the transistor.

In a transistor with an SJ structure using a nitride semiconductor as its element material, it is required to form a deep p-type region in the nitride semiconductor layer. Therefore, there is a need for a method capable of easily forming a deep p-type region.

### BRIEF DESCRIPTION OF THE DRAWINGS

FIG. 1 is a schematic cross-sectional view of a semiconductor device according to a first embodiment;

FIG. 2 is a schematic plan view of the semiconductor device according to the first embodiment;

FIG. 3 is a schematic cross-sectional view showing an example of a semiconductor device manufacturing method according to the first embodiment;

FIG. 4 is a schematic cross-sectional view showing an example of the semiconductor device manufacturing method according to the first embodiment;

FIG. 5 is a schematic cross-sectional view showing an example of the semiconductor device manufacturing method according to the first embodiment;

FIG. 6 is a schematic cross-sectional view showing [0011] an example of the semiconductor device manufacturing method according to the first embodiment;

FIG. 7 is a schematic cross-sectional view showing an example of the semiconductor device manufacturing method according to the first embodiment;

FIG. 8 is a schematic cross-sectional view showing an example of the semiconductor device manufacturing method according to the first embodiment;

FIG. 9 is a schematic cross-sectional view showing an example of the semiconductor device manufacturing method according to the first embodiment;

FIG. 10 is a schematic cross-sectional view showing an example of the semiconductor device manufacturing method according to the first embodiment;

FIG. 11 is a schematic cross-sectional view showing an example of the semiconductor device manufacturing method according to the first embodiment;

FIG. 12 is a schematic cross-sectional view showing an example of the semiconductor device manufacturing method according to the first embodiment;

FIG. 13 is a schematic cross-sectional view of a semiconductor device according to a second embodiment;

FIG. 14 is a schematic plan view of the semiconductor device according to the second embodiment;

FIG. 15 is a schematic cross-sectional view showing an example of a semiconductor device manufacturing method according to the second embodiment;

FIG. 16 is a schematic cross-sectional view showing an example of the semiconductor device manufacturing method according to the second embodiment;

FIG. 17 is a schematic cross-sectional view showing an example of the semiconductor device manufacturing method according to the second embodiment;

FIG. 18 is a schematic cross-sectional view showing an example of the semiconductor device manufacturing method according to the second embodiment;

FIG. 19 is a schematic cross-sectional view showing an example of the semiconductor device manufacturing method according to the second embodiment;

FIG. 20 is a schematic cross-sectional view showing an example of the semiconductor device manufacturing method according to the second embodiment;

FIG. 21 is a schematic cross-sectional view showing an example of the semiconductor device manufacturing method according to the second embodiment;

FIG. 22 is a schematic cross-sectional view showing an example of the semiconductor device manufacturing method according to the second embodiment;

FIG. 23 is a schematic cross-sectional view showing an example of the semiconductor device manufacturing method according to the second embodiment;

FIG. 24 is a schematic cross-sectional view showing an example of the semiconductor device manufacturing method according to the second embodiment;

FIG. 25 is a schematic cross-sectional view showing an example of the semiconductor device manufacturing method according to the second embodiment;

FIG. 26 is a schematic cross-sectional view showing an example of the semiconductor device manufacturing method according to the second embodiment; and

FIG. 27 is a schematic cross-sectional view showing an example of the semiconductor device manufacturing method according to the second embodiment.

### DETAILED DESCRIPTION

A semiconductor device manufacturing method of embodiments includes: forming a mask material on a surface of a nitride semiconductor layer including a first n-type region, the mask material having a plurality of openings repeatedly arranged in a first direction parallel to the surface and extending in a second direction parallel to the surface and perpendicular to the first direction; performing first processing for implanting at least one substance selected from a group consisting of hydrogen (H), helium (He), and electrons into a first region of the nitride semiconductor layer by using the mask material as a mask; performing a first ion implantation for implanting p-type impurities into a second region shallower than the first region by using the mask material as a mask, after the first processing; performing a first heat treatment at a first temperature simultaneously with the first ion implantation or after the first ion implantation; performing a second ion implantation for implanting nitrogen (N) into the nitride semiconductor layer by using the mask material as a mask, after the first heat treatment; and performing a second heat treatment at a second temperature simultaneously with the second ion implantation or after the second ion implantation.

Hereinafter, embodiments will be described with reference to the accompanying diagrams. In the following description, the same or similar members and the like will be denoted by the same reference numerals, and the description of the members and the like once described will be omitted as appropriate.

In this specification, the “nitride semiconductor layer” and the “nitride semiconductor region” contain “GaN-based semiconductor”. The “GaN-based semiconductor” is a general term for gallium nitride (GaN), aluminum nitride (AlN), indium nitride (InN), and semiconductors having an intermediate composition thereof.

In this specification, in order to show the positional relationship of components and the like, the upper direction of the diagram is described as “upper” and the lower direction of the diagram is described as “lower”. In this specification, the concepts of “upper” and “lower” do not necessarily indicate the relationship with the direction of gravity.

In addition, in the following description, when there are notations of n⁺⁺, n⁺, n, n⁻, p⁺, p, and p⁻, these indicate the relative high and low of the impurity concentration in each conductive type. That is, n⁺⁺indicates that the n-type impurity concentration is relatively higher than n⁺, n⁺ indicates that the n-type impurity concentration is relatively higher than n, and n-indicates that the n-type impurity concentration is relatively lower than n. In addition, p⁺ indicates that the p-type impurity concentration is relatively higher than p, and p-indicates that the p-type impurity concentration is relatively lower than p. In addition, n⁺-type and n⁻-type may be simply described as n-type, and p⁺-type and p⁻-type may be simply described as p-type. Unless otherwise specified, the impurity concentration in each region is represented by, for example, the value of the impurity concentration in the central portion of each region.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of an impurity region can be calculated from, for example, an SCM image.

In addition, the depth of a region formed by ions implanted into the nitride semiconductor layer by ion implantation can be calculated from the accelerating voltage and the dose in the ion implantation. For example, the distance from the surface of the nitride semiconductor layer to the point where the atomic concentration of implanted ions becomes equal to or less than 1E15 cm⁻³ is defined as the depth of the region.

In addition, the depth of a region formed by electrons injected into the nitride semiconductor layer by an electron beam can be calculated from the accelerating voltage and the dose of the electron beam. For example, the distance from the surface of the nitride semiconductor layer to the point where the concentration of injected electrons becomes equal to or less than 1E15 cm⁻³ is defined as the depth of the region.

### First Embodiment

A semiconductor device according to a first embodiment includes: a first electrode; a second electrode; a nitride semiconductor layer having a first face provided between the first electrode and the second electrode and parallel to a first direction and a second direction perpendicular to the first direction and a second face parallel to the first and second directions and facing the first face and including a first nitride semiconductor region of p-type and a second nitride semiconductor region of n-type arranged alternately in the first direction, a third nitride semiconductor region of p-type provided between the second nitride semiconductor region and the first face, and a fourth nitride semiconductor region of n-type provided between the third nitride semiconductor region and the first face; a gate electrode provided on the first face side of the nitride semiconductor layer, facing the third nitride semiconductor region, and extending in the second direction; and a gate insulating layer provided between the gate electrode and the nitride semiconductor layer. The nitrogen vacancy level density of the first nitride semiconductor region measured by deep level transient spectroscopy (DLTS) is lower than the nitrogen vacancy level density of the second nitride semiconductor region measured by DLTS.

A semiconductor device manufacturing method according to the first embodiment includes: forming a mask material on a surface of a nitride semiconductor layer including a first n-type region, the mask material having a plurality of openings repeatedly arranged in a first direction parallel to the surface and extending in a second direction parallel to the surface and perpendicular to the first direction; performing first processing for implanting at least one substance selected from a group consisting of hydrogen (H), helium (He), and electrons into a first region of the nitride semiconductor layer by using the mask material as a mask; performing a first ion implantation for implanting p-type impurities into a second region shallower than the first region by using the mask material as a mask, after the first processing; performing a first heat treatment at a first temperature simultaneously with the first ion implantation or after the first ion implantation; performing a second ion implantation for implanting nitrogen (N) into the nitride semiconductor layer by using the mask material as a mask, after the first heat treatment; and performing a second heat treatment at a second temperature simultaneously with the second ion implantation or after the second ion implantation.

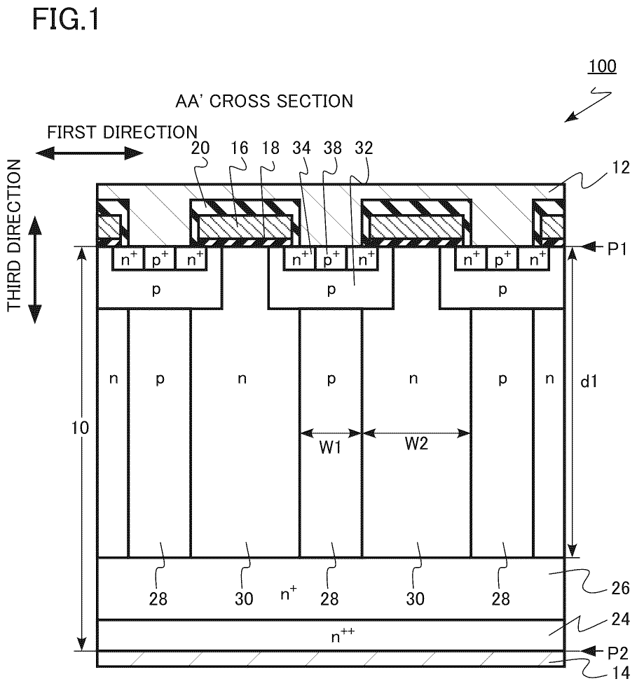

FIG. 1 is a schematic cross-sectional view of the semiconductor device according to the first embodiment. The semiconductor device according to the first embodiment is a planar gate type vertical MOSFET 100 using a nitride semiconductor. The MOSFET 100 is an n-channel MOSFET having electrons as carriers. The MOSFET 100 has a superjunction structure (SJ structure).

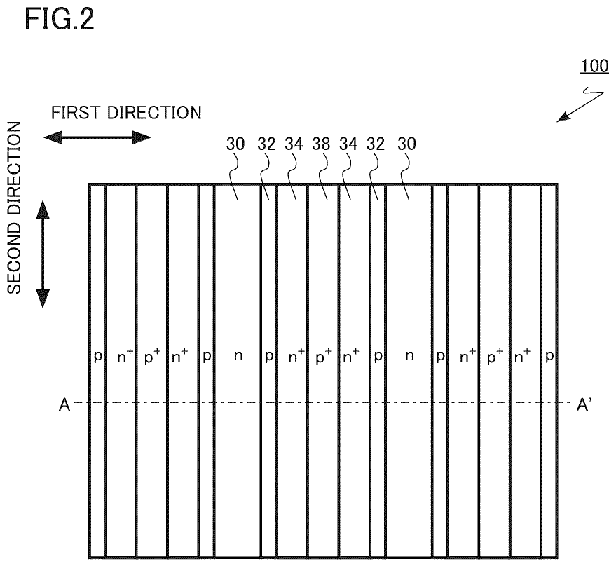

FIG. 2 is a schematic plan view of the semiconductor device according to the first embodiment. FIG. 2 is a plan view of a first face (P1 in FIG. 1) in FIG. 1. FIG. 1 is a cross-sectional view taken along the line AA′ of FIG. 2.

The MOSFET 100 includes a nitride semiconductor layer 10, a source electrode 12 (first electrode), a drain electrode 14 (second electrode), a gate electrode 16, a gate insulating layer 18, and an interlayer insulating layer 20.

The nitride semiconductor layer 10 has an n⁺⁺-type drain region 24, an n⁺-type buffer region 26, a p-type p-pillar region 28 (first nitride semiconductor region), an n-type n-pillar region 30 (second nitride semiconductor region), a p-type body region 32 (third nitride semiconductor region), an n⁺-type source region 34 (fourth nitride semiconductor region), and a p⁺-type contact region 38.

The nitride semiconductor layer 10 is provided between the source electrode 12 and the drain electrode 14. The nitride semiconductor layer 10 has a first face (“P1” in FIG. 1) and a second face (“P2” in FIG. 1). Hereinafter, the first face P1 is also referred to as a surface, and the second face P2 is also referred to as a back surface. The second face P2 is opposite to the first face P1.

The first direction and the second direction are directions parallel to the first face P1. In addition, the second direction is a direction perpendicular to the first direction. In addition, the third direction is a direction perpendicular to the first face P1. The third direction is a direction perpendicular to the first direction and the second direction.

Hereinafter, “depth” means a depth with respect to the first face P1. In addition, “thickness” means a length in the third direction.

The nitride semiconductor layer 10 is, for example, a gallium nitride. The nitride semiconductor layer 10 is, for example, a single crystal gallium nitride. The thickness of the nitride semiconductor layer 10 is, for example, equal to or more than 5 μm and equal to or less than 500 μm.

The gate electrode 16 is provided on the first face P1 side of the nitride semiconductor layer 10. The gate electrode 16 is provided between the source electrode 12 and the drain electrode 14. The gate electrode 16 extends in the second direction.

The gate electrode 16 is a conductive layer. The gate electrode 16 is, for example, polycrystalline silicon containing p-type impurities or n-type impurities.

The gate insulating layer 18 is provided between the gate electrode 16 and the nitride semiconductor layer 10. The gate insulating layer 18 is provided between the gate electrode 16 and each of the source region 34, the body region 32, and the n-pillar region 30.

The gate insulating layer 18 is, for example, a silicon oxide film. As the gate insulating layer 18, for example, a high dielectric constant insulating film having a higher dielectric constant than the silicon oxide film can be applied. In addition, as the gate insulating layer 18, for example, a stacked film of a silicon oxide film and a high dielectric constant insulating film can also be applied.

The interlayer insulating layer 20 is provided on the gate electrode 16. The interlayer insulating layer 20 is, for example, a silicon oxide film. The interlayer insulating layer 20 electrically separates the gate electrode 16 and the source electrode 12 from each other.

The source electrode 12 is provided on the first face P1 side of the nitride semiconductor layer 10. The source electrode 12 is provided on the first face P1 of the nitride semiconductor layer 10. The source electrode 12 is in contact with the source region 34 and the contact region 38.

The source electrode 12 contains metal. The metal forming the source electrode 12 has, for example, a stacked structure of titanium (Ti) and aluminum (Al). The source electrode 12 is, for example, a titanium nitride. The source electrode 12 may contain metal nitride, metal silicide, or metal carbide in contact with the nitride semiconductor layer 10.

The drain electrode 14 is provided on the second face P2 side of the nitride semiconductor layer 10. The drain electrode 14 is provided on the second face P2 of the nitride semiconductor layer 10. The drain electrode 14 is in contact with the drain region 24.

The drain electrode 14 is, for example, a metal or a metal semiconductor compound. The drain electrode 14 contains, for example, a material selected from the group consisting of titanium nitride (TiN), nickel silicide (NiSi), titanium (Ti), nickel (Ni), silver (Ag), and gold (Au).

The n⁺⁺-type drain region 24 is provided on the second face P2 side of the nitride semiconductor layer 10. The drain region 24 is provided between the second face P2 and each of the p-pillar region 28 and the n-pillar region 30.

The drain region 24 contains, for example, silicon (Si) or oxygen (O) as an n-type impurity. The n-type impurity concentration of the drain region 24 is higher than the n-type impurity concentration of the n-pillar region 30. The n-type impurity concentration of the drain region 24 is, for example, equal to or more than 1×10¹⁸ cm⁻³ and equal to or less than 1×10²¹ cm⁻³.

The n⁺-type buffer region 26 is provided on the drain region 24. The buffer region 26 is provided between the second face P2 and each of the p-pillar region 28 and the n-pillar region 30. The p-pillar region 28 and the n-pillar region 30 are in contact with, for example, the buffer region 26.

The n-type impurity concentration of the buffer region 26 is, for example, lower than the n-type impurity concentration of the drain region 24. The n-type impurity concentration of the buffer region 26 is, for example, higher than the n-type impurity concentration of the n-pillar region 30.

The buffer region 26 contains, for example, silicon (Si) or oxygen (O) as an n-type impurity. The n-type impurity concentration of the buffer region 26 is, for example, equal to or more than 1×10¹⁶ cm⁻³ and equal to or less than 1×10²⁰ cm⁻³.

The p-type p-pillar region 28 and the n-type n-pillar region 30 are provided between the drain region 24 and the first face P1. The p-pillar region 28 and the n-pillar region 30 are provided between the buffer region 26 and the first face P1.

The p-pillar region 28 and the n-pillar region 30 are alternately arranged in the first direction. The p-pillar region 28 and the n-pillar region 30 form a so-called superjunction structure (SJ structure).

In the MOSFET 100 having the SJ structure, a depletion layer extends in a lateral direction (first direction) in the p-pillar region 28 and the n-pillar region 30 during off-operation. Since the depletion layer extends in the lateral direction, the electric field strength in the nitride semiconductor layer 10 is reduced and accordingly, a high breakdown voltage can be realized.

The p-pillar region 28 contains, for example, carbon (C) or magnesium (Mg) as a p-type impurity. The p-type impurity concentration of the p-pillar region 28 is, for example, equal to or more than 5×10¹⁵ cm⁻³ and equal to or less than 5×10¹⁷ cm⁻³.

The n-pillar region 30 contains, for example, silicon (Si) or oxygen (O) as an n-type impurity. The n-type impurity concentration of the n-pillar region 30 is, for example, equal to or more than 5×10¹⁵ cm⁻³ and equal to or less than 5×10¹⁷ cm⁻³.

For example, assuming that the width of the p-pillar region 28 in the second direction is W1, the p-type impurity concentration of the p-pillar region 28 is N1, the width of the n-pillar region 30 in the second direction is W2, and the n-type impurity concentration of the n-pillar region 30 is N2, the following relationship is satisfied.

0.8≤(W1×N1)/(W2×N2)≤1.2

The aspect ratio (d1/W1) between the depth d1 of the p-pillar region 28 in the third direction and the width (W1 in FIG. 1) of the p-pillar region 28 in the second direction is, for example, equal to or more than 3 and equal to or less than 100. The aspect ratio (d1/W1) is preferably equal to or more than 4 and equal to or less than 50. The aspect ratio (d1/W1) is more preferably equal to or more than 5 and equal to or less than 25. The aspect ratio (d1/W1) is most preferably equal to or more than 10 and less than 20. The depth d1 of the p-pillar region 28 in the third direction perpendicular to the first face is, for example, equal to or more than 4 μm and equal to or less than 500 μm. The depth d1 is preferably equal to or more than 5 μm and equal to or less than 100 μm. The depth d1 is more preferably equal to or more than 5 μm and equal to or less than 50 μm. The depth d1 is even more preferably equal to or more than 5 μm and equal to or less than 20 μm.

The nitrogen vacancy level density of the p-pillar region 28, which is measured by deep level transient spectroscopy (DLTS), is lower than the nitrogen vacancy level density of the n-pillar region 30 measured by DLTS. The nitrogen vacancy level density of the p-pillar region 28 is, for example, equal to or more than 0.1% and equal to or less than 50% of the nitrogen vacancy level density of the n-pillar region 30. The nitrogen vacancy level density of the p-pillar region 28 is preferably equal to or more than 0.1% and equal to or less than 10% of the nitrogen vacancy level density of the n-pillar region 30, and more preferably equal to or more than 0.1% and equal to or less than 1% of the nitrogen vacancy level density of the n-pillar region 30, for example.

The nitrogen vacancy level density measured by DLTS corresponds to the density of nitrogen vacancies. Therefore, the density of nitrogen vacancies in the p-pillar region 28 is lower than the density of nitrogen vacancies in the n-pillar region 30.

The p-type body region 32 is provided between the n-pillar region 30 and the first face P1. The p-type body region 32 is provided between the p-pillar region 28 and the first face P1.

The body region 32 functions as a channel region of the MOSFET 100. For example, when the MOSFET 100 is turned on, a channel through which electrons flow is formed in a region of the body region 32 in contact with the gate insulating layer 18. A region of the body region 32 in contact with the gate insulating layer 18 is a channel forming region.

The body region 32 contains, for example, carbon (C) or magnesium (Mg) as a p-type impurity. The p-type impurity concentration of the body region 32 is, for example, equal to or more than 5×10¹⁶ cm⁻³ and equal to or less than 5×10¹⁷ cm⁻³.

The depth of the body region 32 is, for example, equal to or more than 0.2 μm and equal to or less than 1.0 μm.

The n⁺-type source region 34 is provided between the body region 32 and the first face P1. The source region 34 is in contact with the source electrode 12. The source region 34 is in contact with the gate insulating layer 18.

The source region 34 contains, for example, silicon (Si) or oxygen (O) as an n-type impurity. The n-type impurity concentration of the source region 34 is, for example, higher than the n-type impurity concentration of the n-pillar region 30. The n-type impurity concentration of the source region 34 is, for example, equal to or more than 1×10¹⁹ cm⁻³ and equal to or less than 1×10²¹ cm⁻³.

The depth of the source region 34 is smaller than the depth of the body region 32. The depth of the source region 34 is, for example, equal to or more than 0.1 μm and equal to or less than 0.3 μm.

The p⁺-type contact region 38 is provided between the body region 32 and the first face P1. The contact region 38 is in contact with the source electrode 12.

As shown in FIG. 2, the contact region 38 has, for example, a stripe shape extending in the second direction.

The contact region 38 contains, for example, carbon (C) or magnesium (Mg) as a p-type impurity. The p-type impurity concentration of the contact region 38 is, for example, higher than the p-type impurity concentration of the body region 32. The p-type impurity concentration of the contact region 38 is, for example, equal to or more than 1×10¹⁸ cm⁻³ and equal to or less than 1×10²¹ cm⁻³.

Next, an example of a semiconductor device manufacturing method according to the first embodiment will be described.

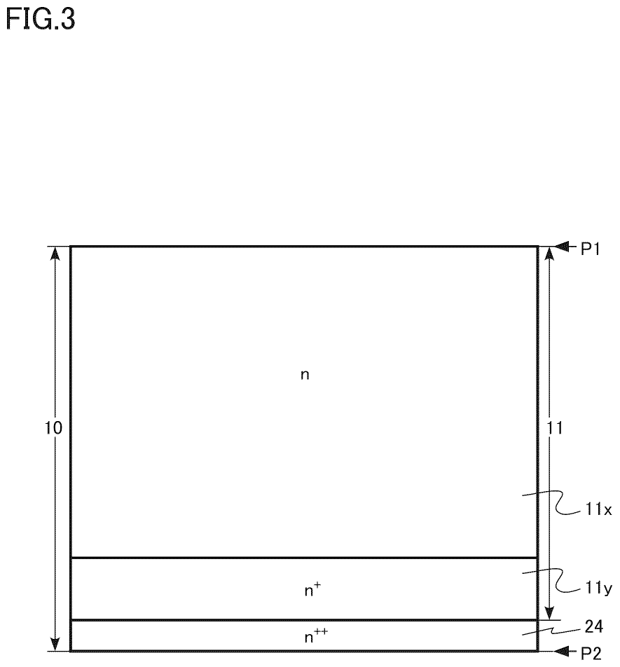

FIGS. 3 to 12 are schematic cross-sectional views showing an example of the semiconductor device manufacturing method according to the first embodiment. FIGS. 3 to 12 show cross sections corresponding to FIG. 1. Hereinafter, a case where the p-type impurity is carbon (C) will be described as an example.

First, the nitride semiconductor layer 10 having the n⁺⁺-type drain region 24 and an epitaxial layer 11 is prepared (FIG. 3). The epitaxial layer 11 is a layer formed on the drain region 24 by epitaxial growth.

The epitaxial layer 11 includes a first n-type region 11x of n-type and a second n-type region 11y of n⁺-type. The first n-type region 11x is provided between the surface of the nitride semiconductor layer 10 and the second n-type region 11y. The first n-type region 11x is in contact with the surface of the nitride semiconductor layer 10. The first n-type region 11x is in contact with the second n-type region 11y.

The second n-type region 11y finally becomes the n⁺-type buffer region 26. A part of the first n-type region 11x finally becomes the n-type n-pillar region 30.

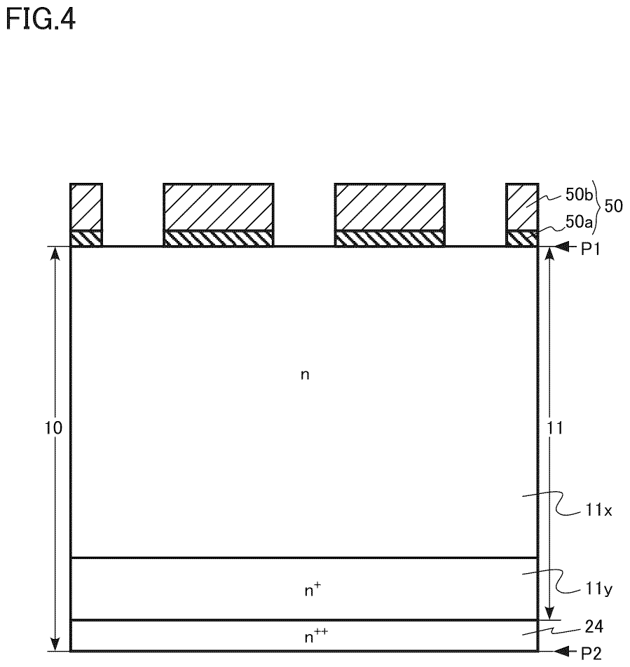

Then, a mask material 50 having a plurality of openings is formed on the surface of the nitride semiconductor layer 10 (FIG. 4). The plurality of openings are repeatedly arranged in the first direction parallel to the surface, and extend in the second direction parallel to the surface and perpendicular to the first direction.

The mask material 50 is, for example, a stacked film of a silicon oxide film 50a and a metal film 50b. The metal film 50b is made of, for example, tungsten.

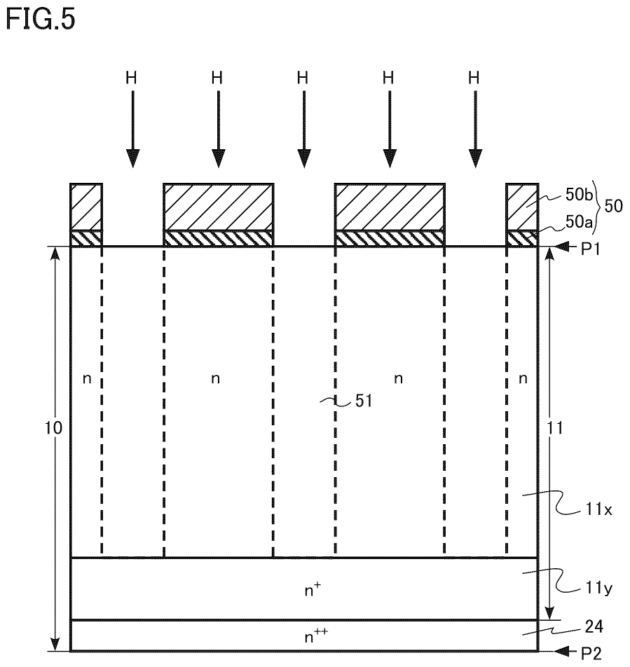

Then, hydrogen (H) is ion-implanted into the nitride semiconductor layer 10 by using the mask material 50 as a mask (FIG. 5). Hydrogen (H) is an example of a substance. The ion implantation of hydrogen (H) is an example of the first processing.

By the ion implantation of hydrogen (H), hydrogen (H) is implanted into a first region 51 of the nitride semiconductor layer 10. Hydrogen (H) is implanted into the entire first region 51. The ion implantation of hydrogen (H) may be performed, for example, in a plurality of steps.

The ion implantation of hydrogen (H) is performed so that the concentration of hydrogen (H) in the first region 51 is, for example, equal to or more than 1×10¹⁵ cm⁻³ and equal to or less than 1×10²¹ cm⁻³.

The depth of the first region 51 is, for example, equal to or more than 5 μm and equal to or less than 50 μm. The first region 51 is in contact with, for example, the second n-type region 11y.

By the ion implantation of hydrogen (H), nitrogen vacancies are formed in the first region 51.

The ion implantation of hydrogen (H) is performed at a temperature equal to or more than 300° C. and equal to or less than 1000° C., for example. For the ion implantation of hydrogen (H), for example, a so-called high-temperature ion implantation method is used.

The ion implantation of hydrogen (H) is performed, for example, while a holder on which the nitride semiconductor layer 10 is placed is held at a temperature equal to or more than 300° C. Since the ion implantation of hydrogen (H) is performed at a temperature equal to or more than 300° C., for example, a degradation in the crystallinity of the nitride semiconductor layer 10 due to the ion implantation is suppressed.

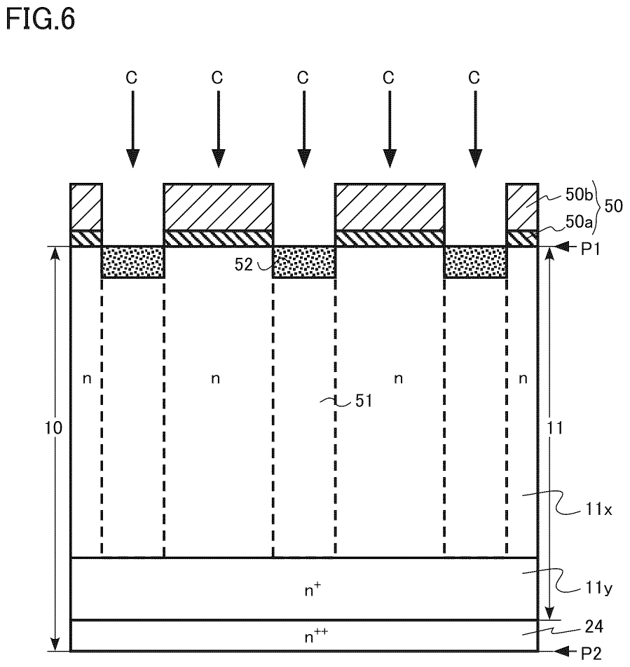

Then, carbon (C) is ion-implanted into the nitride semiconductor layer 10 by using the mask material 50 as a mask (FIG. 6). The ion implantation of carbon (C) is an example of the first ion implantation.

By the ion implantation of carbon (C), carbon (C) is implanted into a second region 52 of the nitride semiconductor layer 10. The second region 52 is shallower than the first region 51.

The second region 52 overlaps, for example, a part of the first region 51. The depth of the first region 51 is, for example, equal to or more than 3 times and equal to or less than 100 times the depth of the second region 52.

The ion implantation of carbon (C) is performed at a temperature equal to or more than 300° C. and equal to or less than 1000° C., for example. For the ion implantation of carbon (C), a so-called high-temperature ion implantation method is used.

In addition, the process of applying heat from the holder to the nitride semiconductor layer 10 during the ion implantation of carbon (C) is an example of the first heat treatment. The temperature of the holder during ion implantation is the first temperature.

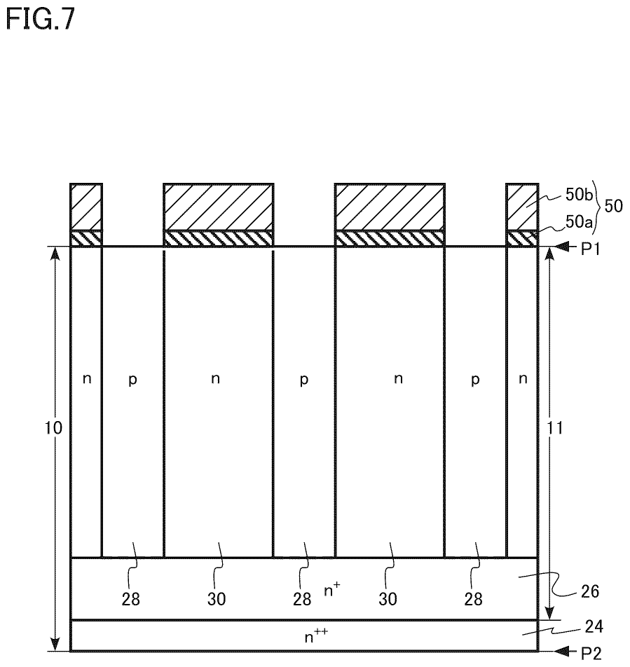

Then, first diffusion annealing is performed (FIG. 7). The first diffusion annealing is performed at a temperature equal to or more than 300° C. and equal to or less than 1000° C., for example. The first diffusion annealing is performed, for example, in a non-oxidizing atmosphere. The first diffusion annealing is performed, for example, in an inert gas atmosphere. The first diffusion annealing is performed, for example, in an argon gas atmosphere.

The first diffusion annealing is an example of the first heat treatment. The temperature of the first diffusion annealing is the first temperature.

When a high-temperature ion implantation method is used for the ion implantation of carbon (C) and then the first diffusion annealing is performed, the first heat treatment includes a first step and a second step. The first step is a heat treatment step for the ion implantation of carbon (C) using a high-temperature ion implantation method, and the second step is a heat treatment step of the first diffusion annealing. The first step is performed simultaneously with the ion implantation of carbon (C).

The heat treatment temperature in the second step is, for example, higher than the heat treatment temperature in the first step. In addition, the heat treatment time of the second step is, for example, longer than the heat treatment time of the first step.

By the ion implantation of carbon (C) using a high-temperature ion implantation method and the first diffusion annealing, carbon (C) diffuses into the first region 51 to form the p-pillar region 28. The region between the p-pillar region 28 and the p-pillar region 28 becomes the n-pillar region 30.

In addition, when a high-temperature ion implantation method is used for the ion implantation of carbon (C), if carbon (C) can sufficiently diffuse into the first region 51 during the ion implantation of carbon (C), the first diffusion annealing can be omitted. In other words, in the first heat treatment, it is possible to perform only the first step and omit the second step.

On the other hand, when the ion implantation of carbon (C) is performed at room temperature, the first diffusion annealing is required to diffuse the carbon (C) into the first region 51. In other words, in the first heat treatment, it is possible to omit the first step and perform only the second step.

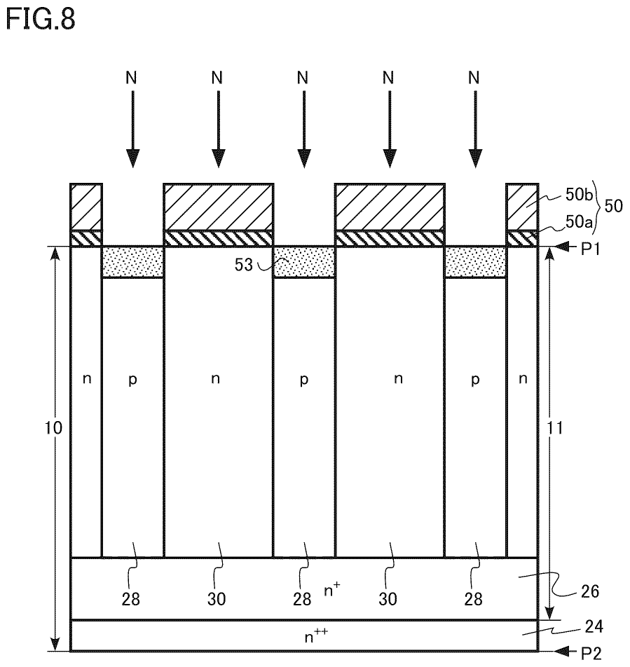

Then, a second ion implantation, which is the ion implantation of nitrogen (N) into the nitride semiconductor layer 10, is performed by using the mask material 50 as a mask (FIG. 8). By the ion implantation of nitrogen (N), nitrogen (N) is implanted into a third region 53. The third region 53 is shallower than the first region 51.

The ion implantation of nitrogen (N) is performed at a temperature equal to or more than 300° C. and equal to or less than 1000° C., for example. For the ion implantation of nitrogen (N), a so-called high-temperature ion implantation method is used.

In addition, the process of applying heat from the holder to the nitride semiconductor layer 10 during the ion implantation of nitrogen (N) is an example of the second heat treatment. The temperature of the holder during ion implantation is the second temperature.

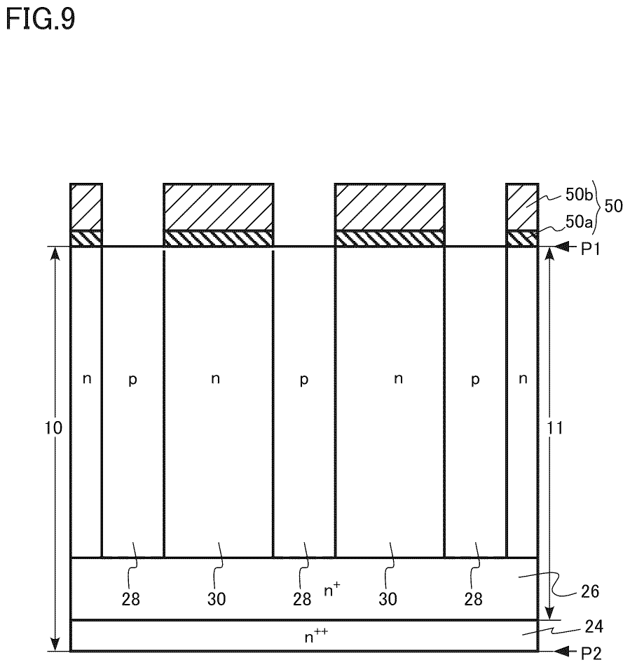

Then, second diffusion annealing is performed (FIG. 9). The second diffusion annealing is performed at a temperature equal to or more than 300° C. and equal to or less than 1000° C., for example. The second diffusion annealing is performed, for example, in a non-oxidizing atmosphere. The second diffusion annealing is performed, for example, in an inert gas atmosphere. The second diffusion annealing is performed, for example, in an argon gas atmosphere.

The second diffusion annealing is an example of the second heat treatment. The temperature of the second diffusion annealing is the second temperature.

When a high-temperature ion implantation method is used for the ion implantation of nitrogen (N) and then the second diffusion annealing is performed, the second heat treatment includes a first step and a second step. The first step is a heat treatment step for the ion implantation of nitrogen (N) using a high-temperature ion implantation method, and the second step is a heat treatment step of the second diffusion annealing. The first step is performed simultaneously with the ion implantation of nitrogen (N).

The heat treatment temperature in the second step is, for example, higher than the heat treatment temperature in the first step. In addition, the heat treatment time of the second step is, for example, longer than the heat treatment time of the first step.

By the ion implantation of nitrogen (N) using a high-temperature ion implantation method and the second diffusion annealing, nitrogen (N) diffuses into the p-pillar region 28.

In addition, when a high-temperature ion implantation method is used for the ion implantation of nitrogen (N), if nitrogen (N) can sufficiently diffuse into the p-pillar region 28 during the ion implantation of nitrogen (N), the second diffusion annealing can be omitted. In other words, in the second heat treatment, it is possible to perform only the first step and omit the second step.

On the other hand, when the ion implantation of nitrogen (N) is performed at room temperature, the second diffusion annealing is required to diffuse the nitrogen (N) into the p-pillar region 28. In other words, in the second heat treatment, it is possible to omit the first step and perform only the second step.

Then, the mask material 50 is removed. The mask material 50 is removed by using, for example, a wet etching method.

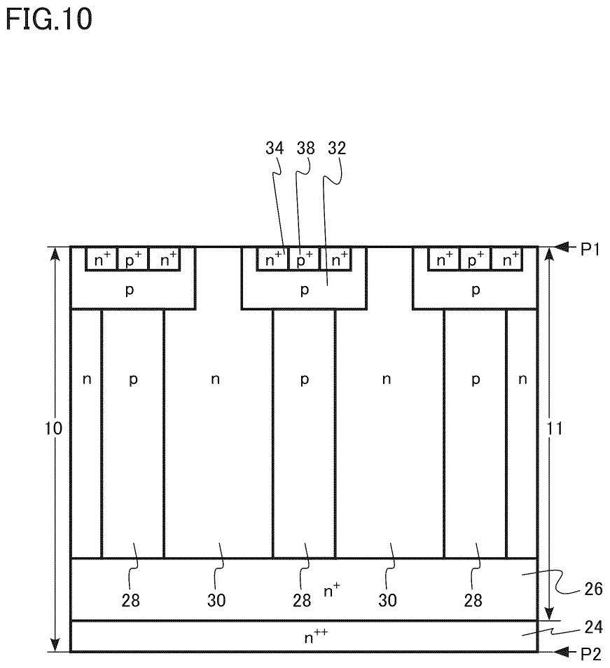

Then, the p-type body region 32, the n⁺-type source region 34, and the p⁺-type contact region 38 are formed in the epitaxial layer 11 by using known lithography method and ion implantation method (FIG. 10).

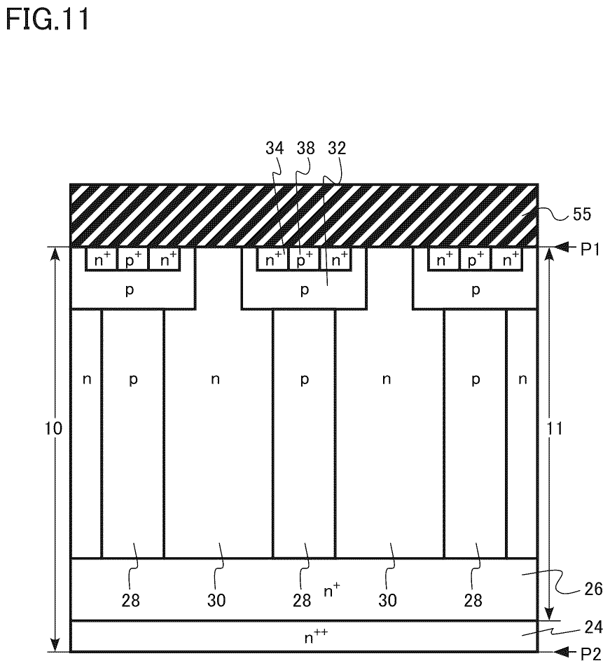

Then, an aluminum nitride layer 55 is formed on the surface of the nitride semiconductor layer 10 (FIG. 11). The aluminum nitride layer 55 is an example of a covering layer.

In addition, the material of the covering layer is not limited to aluminum nitride. The material of the covering layer is, for example, an insulator. The covering layer is, for example, a silicon oxide, a silicon nitride, or a silicon oxynitride.

The aluminum nitride layer 55 suppresses outward diffusion of hydrogen in the nitride semiconductor layer 10 during activation annealing, for example.

Then, activation annealing is performed. The activation annealing is performed at a temperature equal to or more than 900° C. and equal to or less than 1200° C., for example. The activation annealing is performed, for example, in a hydrogen gas atmosphere. The atmosphere for the activation annealing is not limited to the hydrogen gas atmosphere. For example, the activation annealing is performed in a non-oxidizing atmosphere containing argon, nitrogen, or helium. Since the activation annealing is performed in a hydrogen gas atmosphere, outward diffusion of hydrogen in the nitride semiconductor layer 10 is suppressed.

The activation annealing is an example of the third heat treatment. The temperature of the activation annealing is the third temperature. The third temperature is, for example, higher than the first temperature of the first heat treatment and the second temperature of the second heat treatment.

By the activation annealing, ion-implanted carbon (C) enters the nitrogen sites of the gallium nitride to become electrically activated. The electrically activated carbon functions as a p-type impurity. The activated carbon functions as an acceptor.

For example, at least a part of the carbon enters the nitrogen sites of the gallium nitride as hydrogen-bonded carbon. By forming hydrogen-bonded carbon, carbon more readily enters the nitrogen sites of the gallium nitride. Since carbon more readily enters the nitrogen sites of the gallium nitride, the concentration of electrically active p-type impurities can ultimately be increased. However, when carbon has entered the nitrogen sites of the gallium nitride as hydrogen-bonded carbon, the carbon is electrically inactive.

In addition, the activation annealing causes the ion-implanted nitrogen (N) to fill the nitrogen vacancies formed by the ion implantation of hydrogen (H).

In addition, if, by the first heat treatment and the second heat treatment, carbon (C) sufficiently enters the nitrogen sites of the gallium nitride and nitrogen (N) sufficiently fills the nitrogen vacancies, the activation annealing can be omitted.

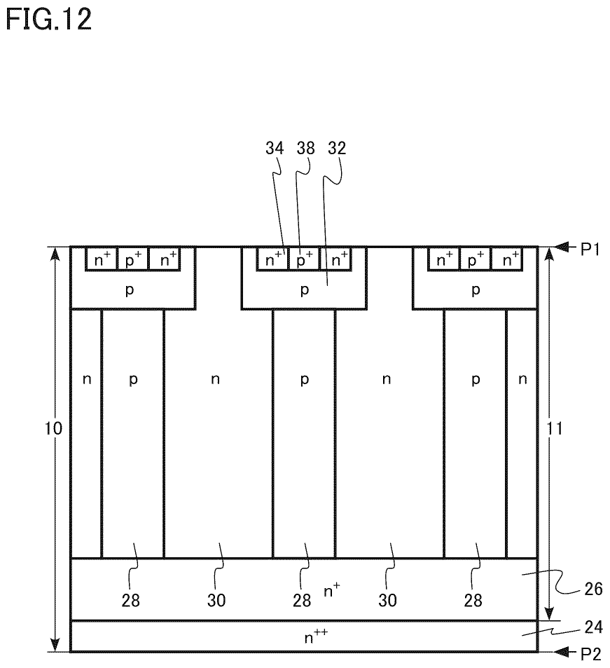

Then, the aluminum nitride layer 55 on the surface of the nitride semiconductor layer 10 is removed by using a known wet etching method (FIG. 12). The surface of the nitride semiconductor layer 10 is exposed.

Then, hydrogen desorption annealing is performed. The hydrogen desorption annealing is performed at a temperature equal to or more than 300° C. and equal to or less than 900° C., for example. The hydrogen desorption annealing is performed, for example, in a nitrogen gas atmosphere. The hydrogen desorption annealing is performed in a non-oxidizing atmosphere containing argon, nitrogen, or helium, for example. The hydrogen desorption annealing is performed, for example, in a hydrogen-free atmosphere.

The hydrogen desorption annealing is an example of the fourth heat treatment. The temperature of the hydrogen desorption annealing is the fourth temperature.

Since the aluminum nitride layer 55 has been removed, outward diffusion of hydrogen from the nitride semiconductor layer 10 is promoted during the hydrogen desorption annealing.

By the hydrogen desorption annealing, the hydrogen in the hydrogen-bonded carbon that has entered the nitrogen sites of the gallium nitride is separated from the carbon, and only the carbon is left in the nitrogen sites to become electrically activated. The electrically activated carbon functions as a p-type impurity. The activated carbon functions as an acceptor.

In addition, for example, if there is a large amount of carbon that has entered the nitrogen sites of gallium nitride as a simple substance or if there is a small amount of carbon that has entered the nitrogen sites of gallium nitride as hydrogen-bonded carbon, it is possible to omit the hydrogen desorption annealing.

Then, using a known process techniques, the gate insulating layer 18, the gate electrode 16, the interlayer insulating layer 20, the source electrode 12, and the drain electrode 14 are formed.

By the manufacturing method described above, the MOSFET 100 shown in FIG. 1 is manufactured.

Next, the function and effect of the semiconductor device and the semiconductor device manufacturing method according to the first embodiment will be described.

The MOSFET 100 has an SJ structure formed by the p-pillar region 28 and the n-pillar region 30. In the SJ structure, a depletion layer extending in the lateral direction within the p-pillar region 28 and the n-pillar region 30 reduces the electric field strength in the semiconductor, thereby realizing a high breakdown voltage of the MOSFET 100. In addition, it is possible to increase the n-type impurity concentration of the n-pillar region 30 by having the SJ structure. Therefore, the on-resistance of the MOSFET 100 is reduced.

In the MOSFET 100, the nitrogen vacancy level density of the p-pillar region 28, which is measured by deep level transient spectroscopy (DLTS), is lower than the nitrogen vacancy level density of the n-pillar region 30 measured by DLTS. The nitrogen vacancy level density measured by DLTS corresponds to the density of nitrogen vacancies. The density of nitrogen vacancies in the p-pillar region 28 is lower than the density of nitrogen vacancies in the n-pillar region 30.

As described above, in the SJ structure, a depletion layer extending in the lateral direction within the p-pillar region 28 and the n-pillar region 30 reduces the electric field strength in the semiconductor, thereby realizing a high breakdown voltage of the MOSFET 100. The presence of nitrogen vacancies shortens the lifetime of carriers in a nitride semiconductor. For example, the presence of nitrogen vacancies shortens the lifetime of holes in the p-pillar region 28 and the lifetime of electrons in the n-pillar region 30. In particular, the presence of nitrogen vacancies shortens the lifetime of holes compared with the lifetime of electrons.

Since the lifetime of holes are shorter than the lifetime of electrons, if the density of nitrogen vacancies in the p-pillar region 28 and the density of nitrogen vacancies in the n-pillar region 30 are the same, the balance between temporal changes in the depletion layer width of the p-pillar region 28 and the depletion layer width of the n-pillar region 30 is lost. Therefore, there is a possibility that the breakdown voltage of the MOSFET will decrease.

In the MOSFET 100, since the density of nitrogen vacancies in the p-pillar region 28 is lower than the density of carbon vacancies in the n-pillar region 30, the balance between temporal changes in the depletion layer width of the p-pillar region 28 and the depletion layer width of the n-pillar region 30 is maintained. Therefore, a high breakdown voltage of the MOSFET 100 can be realized.

In addition, the nitrogen vacancies present in the nitride semiconductor function as n-type impurities, that is, donors. Therefore, if the density of nitrogen vacancies in the p-pillar region 28 is high, a problem occurs that the concentration of electrically active p-type impurities in the p-pillar region 28 cannot be increased. In the MOSFET 100, since the density of nitrogen vacancies in the p-pillar region 28 is lower than the density of nitrogen vacancies in the n-pillar region 30, the concentration of electrically active p-type impurities in the p-pillar region 28 can be increased.

In a MOSFET with an SJ structure, it is required to form a deep p-type region in a nitride semiconductor layer. For example, it is required to form a deep p-type region equal to or more than 5 μm. With a normal ion implantation method, it is difficult to implant p-type impurities, such as carbon (C) or magnesium (Mg), into a deep region equal to or more than 5 μm.

For this reason, for example, there is a method in which when forming an SJ structure, epitaxial growth of a nitride semiconductor film, ion implantation of p-type impurities, and activation annealing of p-type impurities are repeatedly performed to form a deep p-type region in the nitride semiconductor layer. This method has a problem in that the manufacturing cost increases because the number of steps increases. In addition, this method requires alignment for ion implantation of p-type impurities. For this reason, there is a problem that this method is not suitable for scaling-down of MOSFETS.

For example, there is a method in which when forming an SJ structure, a channeling ion implantation is performed to implant ions along a specific crystal axis when ion-implanting p-type impurities, thereby forming a deep p-type region in the nitride semiconductor layer. In this method, it is necessary to match the crystal orientation of the surface of the nitride semiconductor layer with the ion implantation direction with high precision. Therefore, there is a problem that variations in the depth of the p-type region increase due to variations in the crystal orientation of the surface of the nitride semiconductor layer.

The inventors' investigations using first principle calculation have revealed that the presence of nitrogen vacancies in a nitride semiconductor causes accelerated diffusion of p-type impurities such as carbon (C) and magnesium (Mg). Therefore, it is considered that if nitrogen vacancies can be distributed into the deep region of the nitride semiconductor layer, p-type impurities implanted in the shallow region of the nitride semiconductor layer can diffuse into the deep region by accelerated diffusion, thereby forming a deep p-type region.

In the semiconductor device manufacturing method according to the first embodiment, ion implantation of hydrogen (H) is performed before ion implantation of p-type impurities, forming the deep first region 51 with a high nitrogen vacancy density. Hydrogen (H) has a smaller ion radius than carbon (C) or magnesium (Mg). Therefore, it is easy to implant hydrogen (H) ions into a deep region, for example, equal to or more than 5 μm and equal to or less than 500 μm. In the first region 51, the density of nitrogen vacancies in the nitride semiconductor increases due to damage caused by the ion implantation of hydrogen (H).

After forming the deep first region 51 with a high nitrogen vacancy density, p-type impurities are ion-implanted. Thereafter, p-type impurities are diffused by the first heat treatment. The presence of nitrogen vacancies in the nitride semiconductor causes accelerated diffusion of p-type impurities. Therefore, since p-type impurities are diffused over the entire first region 51, it is possible to form a deep p-type region in the nitride semiconductor layer. As a result, it is possible to form the deep p-pillar region 28 in the nitride semiconductor layer 10.

P-type impurities diffuse along the first region 51 with a high nitrogen vacancy density. Therefore, the diffusion of p-type impurities in the lateral direction is suppressed. As a result, it is possible to form a p-type region with a large depth and a small lateral width, in other words, a p-type region with a large aspect ratio.

In addition, in the semiconductor device manufacturing method according to the first embodiment, after a deep p-type region is formed, nitrogen (N) is ion-implanted. Thereafter, nitrogen (N) is diffused by the second heat treatment. By diffusing nitrogen (N), nitrogen vacancies are filled with nitrogen (N), reducing the density of nitrogen vacancies in the p-pillar region 28.

Therefore, a high breakdown voltage of the MOSFET 100 can be realized. In addition, it is possible to increase the concentration of electrically active p-type impurities in the p-pillar region 28 of the MOSFET 100.

In addition, according to the semiconductor device manufacturing method according to the first embodiment, it is possible to form a deep p-type region in a nitride semiconductor layer by using a simple manufacturing method with a small number of steps.

In addition, in the semiconductor device manufacturing method according to the first embodiment, the ion implantation of hydrogen (H), the ion implantation of p-type impurities, and the ion implantation of nitrogen (N) are performed using the same mask material. Therefore, since the alignment of the mask for ion implantation is not necessary, scaling-down of the MOSFET can be realized.

In addition, since the semiconductor device manufacturing method according to the first embodiment does not depend on channeling ion implantation, it is possible to form a p-type region with the same depth regardless of the crystal orientation of the surface of the nitride semiconductor layer 10. Therefore, according to the semiconductor device manufacturing method according to the first embodiment, it is possible to suppress variations in the depth of the p-type region.

From the viewpoint of promoting the diffusion of p-type impurities by increasing the nitrogen vacancy density, ion implantation of hydrogen (H) is preferably performed so that the concentration of hydrogen (H) in the first region 51 is equal to or more than 1×10¹⁵ cm⁻³, more preferably performed so that the concentration of hydrogen (H) in the first region 51 is equal to or more than 1×10¹⁶ cm⁻³, and even more preferably performed so that the concentration of hydrogen (H) in the first region 51 is equal to or more than 1×10¹⁷ cm⁻³.

From the viewpoint of suppressing a degradation in the crystallinity of the nitride semiconductor layer 10, ion implantation of hydrogen (H) is preferably performed so that the concentration of hydrogen (H) in the first region 51 is equal to or less than 1×10²¹ cm⁻³, more preferably performed so that the concentration of hydrogen (H) in the first region 51 is equal to or less than 1×10²⁰ cm⁻³, and even more preferably performed so that the concentration of hydrogen (H) in the first region 51 is equal to or less than 1×10¹⁹ cm⁻³.

From the viewpoint of suppressing a degradation in the crystallinity of the nitride semiconductor layer 10, ion implantation of hydrogen (H) is preferably performed at a temperature equal to or more than 300° C., more preferably performed at a temperature equal to or more than 500° C., and even more preferably performed at a temperature equal to or more than 900° C.

From the viewpoint of diffusing carbon (C) into the first region 51 during the first ion implantation that is ion implantation of carbon (C), the first ion implantation is preferably performed at a temperature equal to or more than 300° C., more preferably performed at a temperature equal to or more than 500° C., and even more preferably performed at a temperature equal to or more than 900° C.

From the viewpoint of promoting the diffusion of carbon (C) into the first region 51, the temperature of the first diffusion annealing performed after the first ion implantation is preferably equal to or more than 300° C., more preferably equal to or more than 500° C., and even more preferably equal to or more than 900° C.

From the viewpoint of promoting the diffusion of nitrogen (N) into the p-pillar region 28, the second ion implantation that is ion implantation of nitrogen (N) is preferably performed at a temperature equal to or more than 300° C., more preferably performed at a temperature equal to or more than 500° C., and even more preferably performed at a temperature equal to or more than 900° C.

From the viewpoint of promoting the diffusion of nitrogen (N) into the p-pillar region 28, the temperature of the second diffusion annealing performed after ion implantation of nitrogen (N) is preferably equal to or more than 300° C., more preferably equal to or more than 500° C., and even more preferably equal to or more than 900° C.

### First Modification Example

A semiconductor device manufacturing method according to a first modification example of the first embodiment is different from the semiconductor device manufacturing method according to the first embodiment in that the p-type impurity is magnesium (Mg).

When magnesium (Mg) is ion-implanted into the nitride semiconductor layer 10 in the first ion implantation, the ion-implanted magnesium enters the gallium sites of the gallium nitride to become electrically activated by activation annealing. The electrically activated magnesium functions as a p-type impurity. The activated magnesium functions as an acceptor.

Since the ion-implanted nitrogen (N) fills the nitrogen vacancies, magnesium more readily enters the gallium sites rather than the nitrogen sites.

For example, at least a part of the magnesium enters the gallium sites of the gallium nitride as hydrogen-bonded magnesium. By forming hydrogen-bonded magnesium, magnesium more readily enters the gallium sites of the gallium nitride. Since magnesium more readily enters the gallium sites of the gallium nitride, the concentration of electrically active p-type impurities can ultimately be increased. However, when magnesium has entered the gallium sites of the gallium nitride as hydrogen-bonded magnesium, the magnesium is electrically inactive.

By the hydrogen desorption annealing, the hydrogen of the hydrogen-bonded magnesium that has entered the gallium sites of the gallium nitride is separated from the magnesium, and only the magnesium is left in the gallium sites to become electrically activated. The electrically activated magnesium functions as a p-type impurity. The activated magnesium functions as an acceptor.

According to the semiconductor device manufacturing method according to the first modification example of the first embodiment, the same function and effect as in the semiconductor device manufacturing method according to the first embodiment can be achieved.

### Second Modification Example

A semiconductor device manufacturing method according to a second modification example of the first embodiment is different from the semiconductor device manufacturing method according to the first embodiment in that the substance is helium (He) and a third ion implantation in which hydrogen (H) is implanted into the nitride semiconductor layer using a mask material as a mask is performed before the second heat treatment after the first processing.

In the second modification example of the first embodiment, helium (He) is ion-implanted into the nitride semiconductor layer 10 by using the mask material 50 as a mask. Helium (He) is an example of a substance. The ion implantation of helium (He) is an example of the first processing.

For example, after performing the ion implantation of helium (He), before the ion implantation of nitrogen (N) or before the second diffusion annealing, a third ion implantation is performed in which hydrogen (H) is implanted into the nitride semiconductor layer 10 by using the mask material 50 as a mask.

By ion-implanting hydrogen (H) into the nitride semiconductor layer 10, carbon forms hydrogen-bonded carbon. By forming hydrogen-bonded carbon, carbon more readily enters the nitrogen sites of the gallium nitride. Since carbon more readily enters the nitrogen sites of the gallium nitride, the concentration of electrically active p-type impurities can ultimately be increased.

Helium (He) has a smaller ion radius than carbon (C) or magnesium (Mg), similar to hydrogen (H). Therefore, it is easy to implant helium (He) ions into a deep region, for example, equal to or more than 5 μm and equal to or less than 500 μm.

According to the semiconductor device manufacturing method according to the second modification example of the first embodiment, the same function and effect as in the semiconductor device manufacturing method according to the first embodiment can be achieved.

### Third Modification Example

A semiconductor device manufacturing method according to a third modification example of the first embodiment is different from the semiconductor device manufacturing method according to the first embodiment in that the substance is an electron and a third ion implantation in which hydrogen (H) is implanted into the nitride semiconductor layer using a mask material as a mask is performed before the second heat treatment after the first processing.

In the third modification example of the first embodiment, electrons are injected into the nitride semiconductor layer 10 by using the mask material 50 as a mask. Electrons are an example of a substance. The injection of electrons is an example of the first processing.

For example, after performing the injection of electrons, before the ion implantation of nitrogen (N) or before the second diffusion annealing, a third ion implantation is performed in which hydrogen (H) is implanted into the nitride semiconductor layer 10 by using the mask material 50 as a mask.

By ion-implanting hydrogen (H) into the nitride semiconductor layer 10, carbon forms hydrogen-bonded carbon. By forming hydrogen-bonded carbon, carbon more readily enters the nitrogen sites of the gallium nitride. Since carbon more readily enters the nitrogen sites of the gallium nitride, the concentration of electrically active p-type impurities can ultimately be increased.

An electron has a smaller diameter than carbon (C) or magnesium (Mg). Therefore, electrons can be easily injected into a deep region, for example, equal to or more than 5 μm and equal to or less than 500 μm by electron beam irradiation.

According to the semiconductor device manufacturing method according to the third modification example of the first embodiment, the same function and effect as in the semiconductor device manufacturing method according to the first embodiment can be achieved.

As described above, according to the first embodiment and its modification examples, it is possible to realize a semiconductor device with a high breakdown voltage. In addition, according to the first embodiment and its modification examples, it is possible to realize a semiconductor device manufacturing method capable of easily forming a deep p-type region.

### Second Embodiment

A semiconductor device according to a second embodiment is different from the semiconductor device according to the first embodiment in that a nitride semiconductor layer is provided on the first face side, a trench extending in the second direction on the first face is further provided, and a gate electrode is provided in the trench. In addition, a semiconductor device manufacturing method according to the second embodiment is different from the semiconductor device manufacturing method according to the first embodiment in that, before the first processing, a trench is formed in the nitride semiconductor layer using a mask material as a mask. Hereinafter, the description of a part of the content overlapping the first embodiment may be omitted.

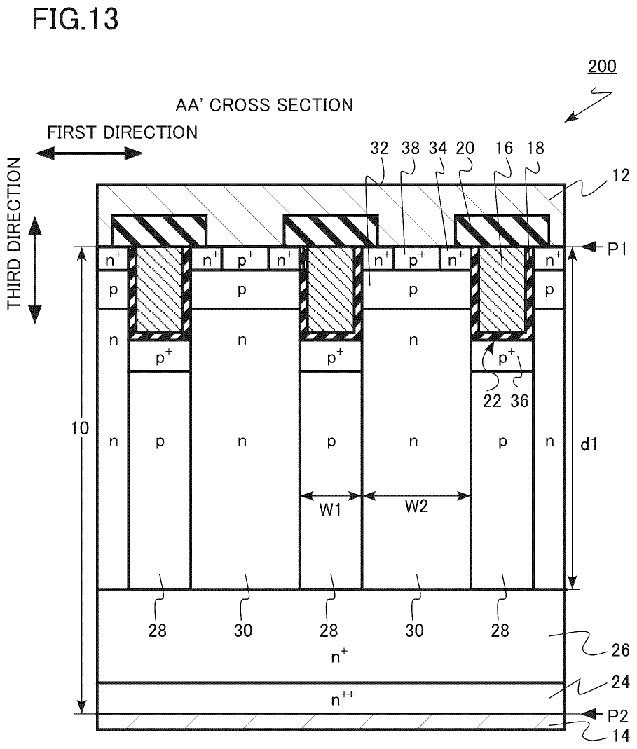

FIG. 13 is a schematic cross-sectional view of the semiconductor device according to the second embodiment. The semiconductor device according to the second embodiment is a trench gate type vertical MOSFET 200 using a nitride semiconductor. The MOSFET 200 is an n-channel MOSFET that uses electrons as carriers. The MOSFET 200 has a superjunction structure (SJ structure).

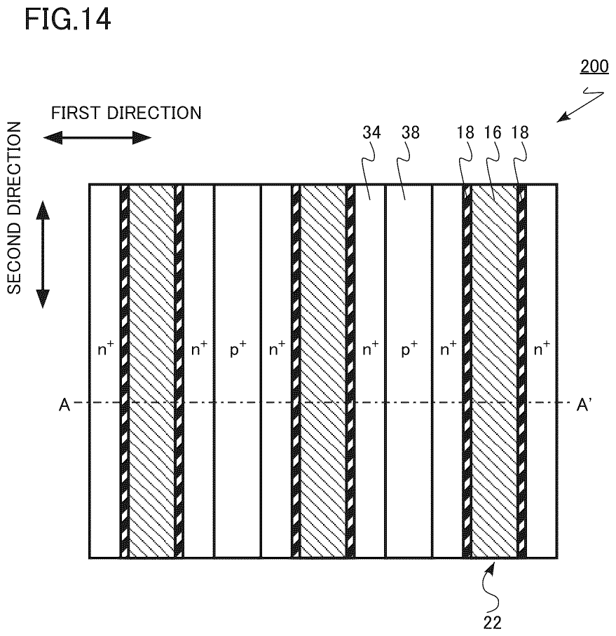

FIG. 14 is a schematic plan view of the semiconductor device according to the second embodiment. FIG. 14 is a plan view of a first face (P1 in FIG. 13) in FIG. 13. FIG. 13 is a cross-sectional view taken along the line AA′ of FIG. 14.

The MOSFET 200 includes a nitride semiconductor layer 10, a source electrode 12 (first electrode), a drain electrode 14 (second electrode), a gate electrode 16, a gate insulating layer 18, and an interlayer insulating layer 20.

The nitride semiconductor layer 10 has a gate trench 22 (trench), an n⁺⁺-type drain region 24, an n⁺-type buffer region 26, a p-type p-pillar region 28 (first nitride semiconductor region), an n-type n-pillar region 30 (second nitride semiconductor region), a p-type body region 32 (third nitride semiconductor region), an n⁺-type source region 34 (fourth nitride semiconductor region), a p⁺-type electric field relaxation region 36, and a p⁺-type contact region 38.

The gate trench 22 is present in the nitride semiconductor layer 10. The gate trench 22 is provided on the first face P1 side of the nitride semiconductor layer 10. The gate trench 22 is a groove formed in the nitride semiconductor layer 10.

The gate trench 22 extends in the second direction as shown in FIG. 14. The gate trench 22 is repeatedly arranged in the first direction as shown in FIG. 14. The pitch between the gate trenches 22 in the first direction is, for example, equal to or more than 1 μm and equal to or less than 5 μm. The depth of the gate trench 22 is, for example, equal to or more than 1 μm and equal to or less than 2 μm. The width of the gate trench 22 in the first direction is, for example, equal to or more than 0.5 μm and equal to or less than 1 μm.

The gate electrode 16 is provided in the gate trench 22. The gate electrode 16 is provided between the source electrode 12 and the drain electrode 14. The gate electrode 16 extends in the second direction.

The gate insulating layer 18 is provided between the gate electrode 16 and the nitride semiconductor layer 10. The gate insulating layer 18 is provided between the gate electrode 16 and each of the source region 34, the body region 32, the electric field relaxation region 36, and the n-pillar region 30.

The p-type p-pillar region 28 and the n-type n-pillar region 30 are provided between the drain region 24 and the first face P1. The p-pillar region 28 and the n-pillar region 30 are provided between the buffer region 26 and the first face P1.

The p-pillar region 28 is provided between the gate trench 22 and the second face P2. The p-pillar region 28 is provided between the gate trench 22 and the buffer region 26.

The p-pillar region 28 and the n-pillar region 30 are arranged alternately in the first direction. The p-pillar region 28 and the n-pillar region 30 form a so-called superjunction structure (SJ structure).

The p-pillar region 28 contains, for example, carbon (C) or magnesium (Mg) as a p-type impurity. The p-type impurity concentration of the p-pillar region 28 is, for example, equal to or more than 5×10¹⁵ cm⁻³ and equal to or less than 5×10¹⁷ cm⁻³.

The n-pillar region 30 contains, for example, silicon (Si) or oxygen (O) as an n-type impurity. The n-type impurity concentration of the n-pillar region 30 is, for example, equal to or more than 5×10¹⁵ cm⁻³ and equal to or less than 5×10¹⁷ cm⁻³.

For example, assuming that the width of the p-pillar region 28 in the second direction is W1, the p-type impurity concentration of the p-pillar region 28 is N1, the width of the n-pillar region 30 in the second direction is W2, and the n-type impurity concentration of the n-pillar region 30 is N2, the following relationship is satisfied.

0.8≤(W1×N1)/(W2×N2)≤1.2

The aspect ratio (d1/W1) between the depth d1 of the p-pillar region 28 in the third direction and the width (W1 in FIG. 13) of the p-pillar region 28 in the second direction is, for example, equal to or more than 3. The depth d1 of the p-pillar region 28 in the third direction perpendicular to the first face is, for example, equal to or more than 5 μm and equal to or less than 10 μm.

The nitrogen vacancy level density of the p-pillar region 28, which is measured by deep level transient spectroscopy (DLTS), is lower than the nitrogen vacancy level density of the n-pillar region 30 measured by DLTS. The nitrogen vacancy level density of the p-pillar region 28 is, for example, equal to or less than 50% of the nitrogen vacancy level density of the n-pillar region 30.

The nitrogen vacancy level density measured by DLTS corresponds to the density of nitrogen vacancies. The density of nitrogen vacancies in the p-pillar region 28 is lower than the density of nitrogen vacancies in the n-pillar region 30.

The p⁺-type electric field relaxation region 36 is provided between the p-pillar region 28 and the gate trench 22. The electric field relaxation region 36 is in contact with the bottom surface of the gate trench 22. The electric field relaxation region 36 is in contact with the gate insulating layer 18. The electric field relaxation region 36 is in contact with the p-pillar region 28.

The electric field relaxation region 36 has a function of relaxing the electric field applied to the gate insulating layer 18 when the MOSFET 200 is turned off. The electric field relaxation region 36 is fixed to, for example, the same electric potential as the electric potential of the source electrode 12.

The electric field relaxation region 36 contains, for example, carbon (C) or magnesium (Mg) as a p-type impurity. The p-type impurity concentration of the electric field relaxation region 36 is higher than the p-type impurity concentration of the p-pillar region 28. The p-type impurity concentration of the electric field relaxation region 36 is, for example, equal to or more than 10 times the p-type impurity concentration of the p-pillar region 28. The p-type impurity concentration of the electric field relaxation region 36 is, for example, equal to or more than 5×10¹⁷ cm⁻³ and equal to or less than 5×10¹⁹ cm⁻³.

Next, an example of a semiconductor device manufacturing method according to the second embodiment will be described.

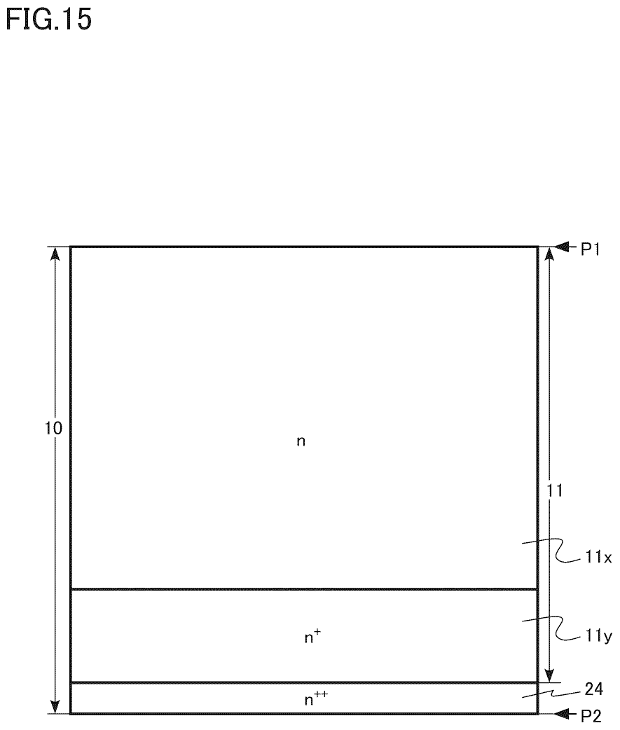

FIGS. 15 to 27 are schematic cross-sectional views showing an example of the semiconductor device manufacturing method according to the second embodiment. FIGS. 15 to 27 show cross sections corresponding to FIG. 13.

First, the nitride semiconductor layer 10 having the n⁺⁺-type drain region 24 and the epitaxial layer 11 is prepared (FIG. 15). The epitaxial layer 11 is a layer formed on the drain region 24 by epitaxial growth.

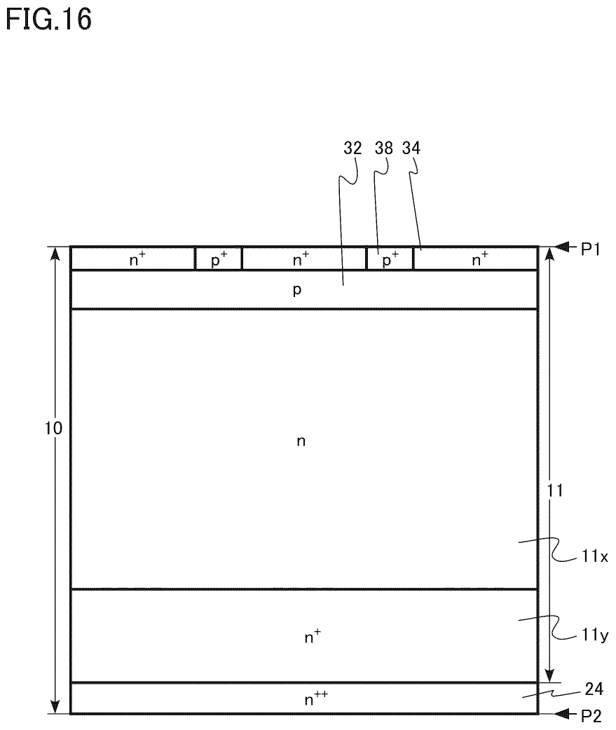

Then, the p-type body region 32, the n⁺-type source region 34, and the p⁺-type contact region 38 are formed in the epitaxial layer 11 by using known lithography method and ion implantation method (FIG. 16).

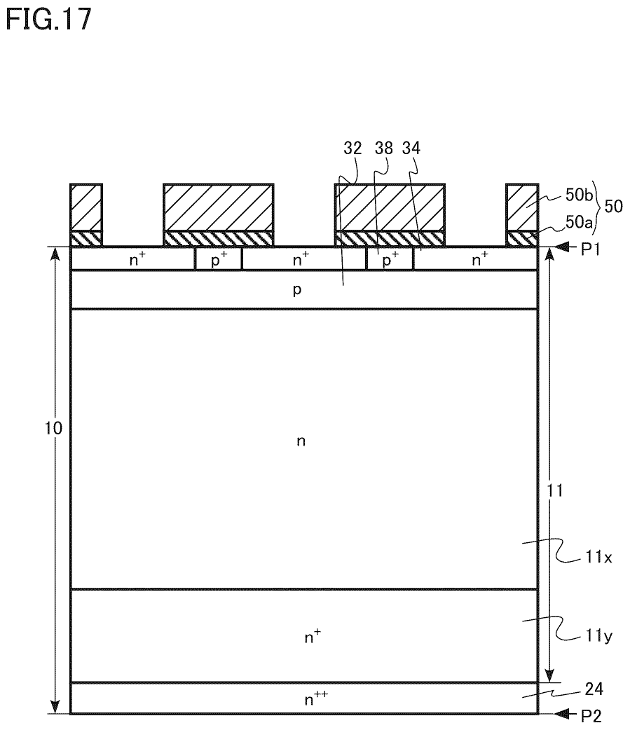

Then, a mask material 50 having an opening is formed on the nitride semiconductor layer 10 (FIG. 17). The mask material 50 is, for example, a stacked film of a silicon oxide film 50a and a metal film 50b.

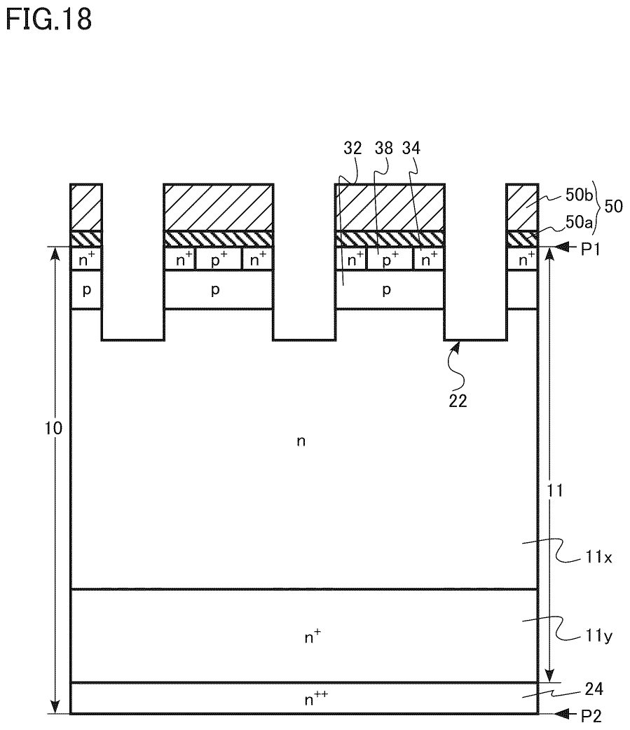

Then, using a known reactive ion etching method, the gate trench 22 is formed by using the mask material 50 as a mask (FIG. 18). The gate trench 22 is formed so as to penetrate the source region 34 and the body region 32.

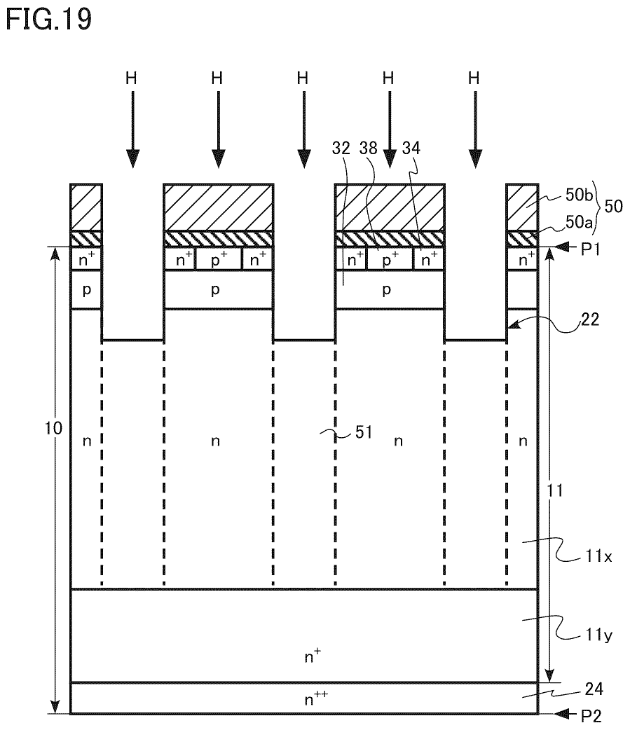

Then, hydrogen (H) is ion-implanted into the nitride semiconductor layer 10 by using the mask material 50 as a mask (FIG. 19). Hydrogen (H) is an example of a substance. Ion implantation of hydrogen (H) is an example of the first processing.

By the ion implantation of hydrogen (H), hydrogen (H) is implanted into the first region 51 of the nitride semiconductor layer 10.

The ion implantation of hydrogen (H) is performed so that the concentration of hydrogen (H) in the first region 51 is, for example, equal to or more than 1×10¹⁵ cm⁻³ and equal to or less than 1×10²¹ cm⁻³.

By the ion implantation of hydrogen (H), nitrogen vacancies are formed in the first region 51.

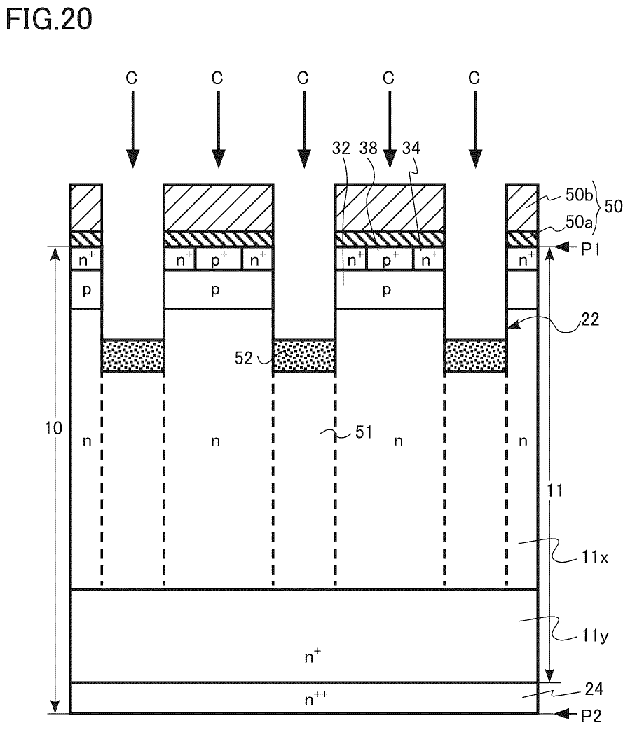

Then, carbon (C) is ion-implanted into the nitride semiconductor layer 10 by using the mask material 50 as a mask (FIG. 20). The ion implantation of carbon (C) is an example of the first ion implantation.

By the ion implantation of carbon (C), carbon (C) is implanted into the second region 52 of the nitride semiconductor layer 10. The second region 52 is shallower than the first region 51.

The ion implantation of carbon (C) is performed at a temperature equal to or more than 300° C. and equal to or less than 1000° C., for example. For the ion implantation of carbon (C), a so-called high-temperature ion implantation method is used.

In addition, the process of applying heat from the holder to the nitride semiconductor layer 10 during the ion implantation of carbon (C) is an example of the first heat treatment. The temperature of the holder during ion implantation is the first temperature.

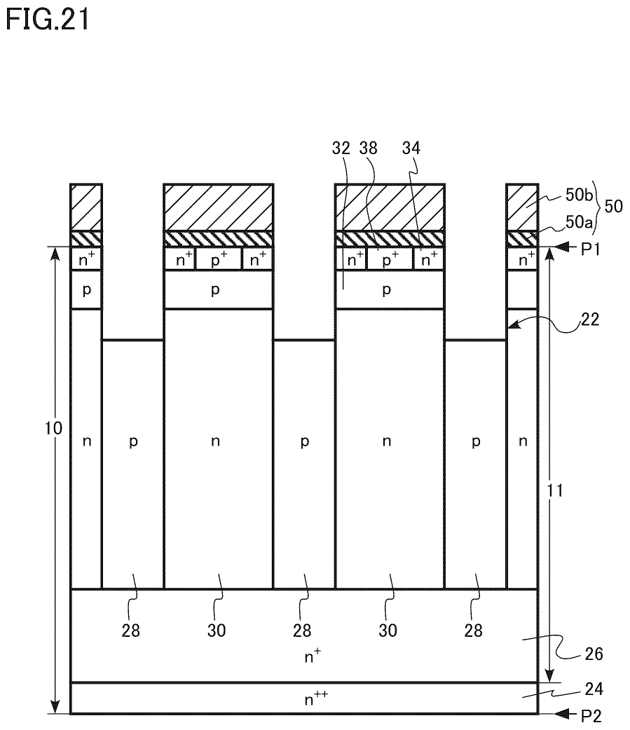

Then, first diffusion annealing is performed (FIG. 21). The first diffusion annealing is performed at a temperature equal to or more than 300° C. and equal to or less than 1000° C., for example. The first diffusion annealing is performed, for example, in a non-oxidizing atmosphere. The first diffusion annealing is performed, for example, in an inert gas atmosphere. The first diffusion annealing is performed, for example, in an argon gas atmosphere.

The first diffusion annealing is an example of the first heat treatment. The temperature of the first diffusion annealing is the first temperature.

By the ion implantation of carbon (C) using a high-temperature ion implantation method and the first diffusion annealing, carbon (C) diffuses into the first region 51 to form the p-pillar region 28. The region between the p-pillar region 28 and the p-pillar region 28 becomes the n-pillar region 30.

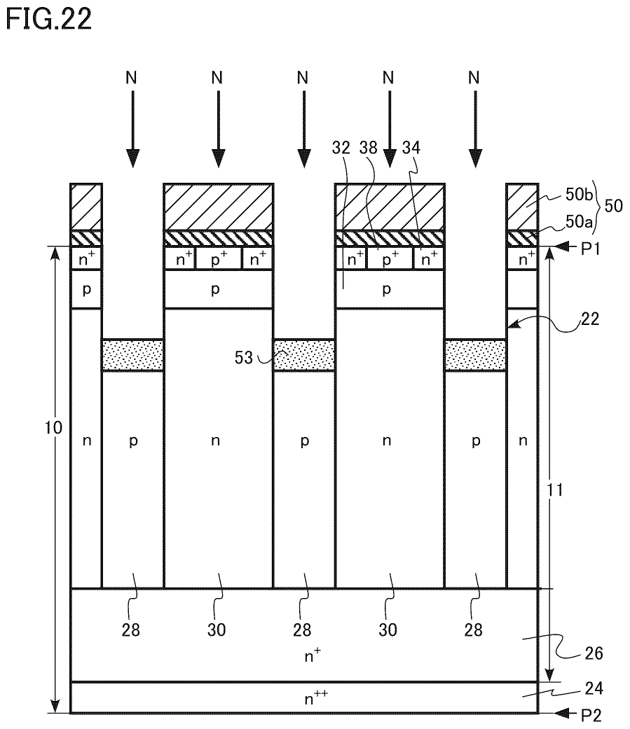

Then, a second ion implantation, which is the ion implantation of nitrogen (N) into the nitride semiconductor layer 10, is performed by using the mask material 50 as a mask (FIG. 22). By the ion implantation of nitrogen (N), nitrogen (N) is implanted into the third region 53. The third region 53 is shallower than the first region 51.

The ion implantation of nitrogen (N) is performed at a temperature equal to or more than 300° C. and equal to or less than 1000° C., for example. For the ion implantation of nitrogen (N), a so-called high-temperature ion implantation method is used.

In addition, the process of applying heat from the holder to the nitride semiconductor layer 10 during the ion implantation of nitrogen (N) is an example of the second heat treatment. The temperature of the holder during ion implantation is the second temperature.

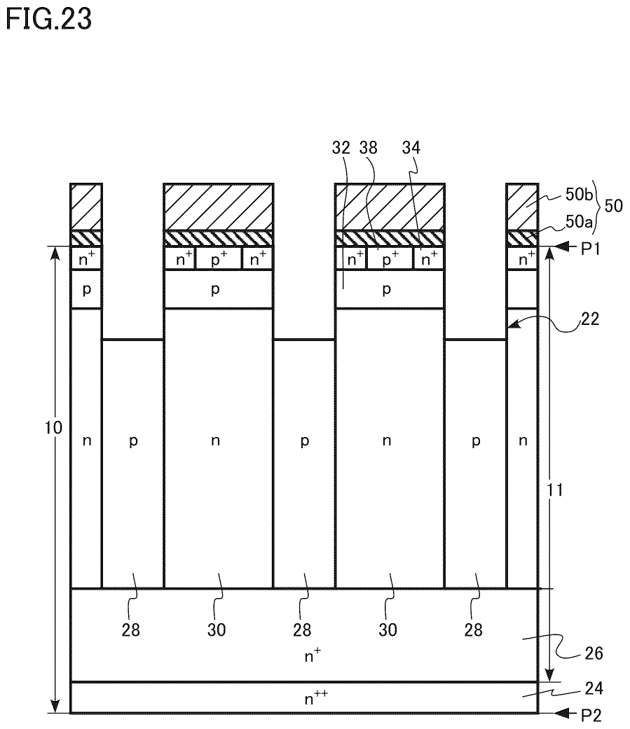

Then, second diffusion annealing is performed (FIG. 23). The second diffusion annealing is performed at a temperature equal to or more than 300° C. and equal to or less than 1000° C., for example. The second diffusion annealing is performed, for example, in a non-oxidizing atmosphere. The second diffusion annealing is performed, for example, in an inert gas atmosphere. The second diffusion annealing is performed, for example, in an argon gas atmosphere.

The second diffusion annealing is an example of the second heat treatment. The temperature of the second diffusion annealing is the second temperature.

By the ion implantation of nitrogen (N) using a high-temperature ion implantation method and the second diffusion annealing, nitrogen (N) diffuses into the p-pillar region 28.

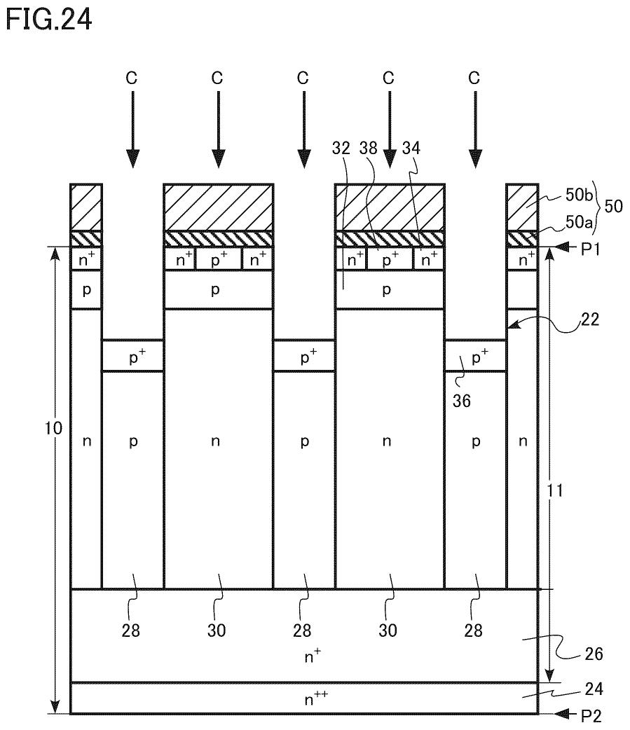

Then, carbon (C) is ion-implanted into the nitride semiconductor layer 10 by using the mask material 50 as a mask (FIG. 24). By the ion implantation of carbon (C), the p⁺-type electric field relaxation region 36 is formed at the bottom of the gate trench 22.

Then, the mask material 50 is removed. The mask material 50 is removed by using, for example, a wet etching method.

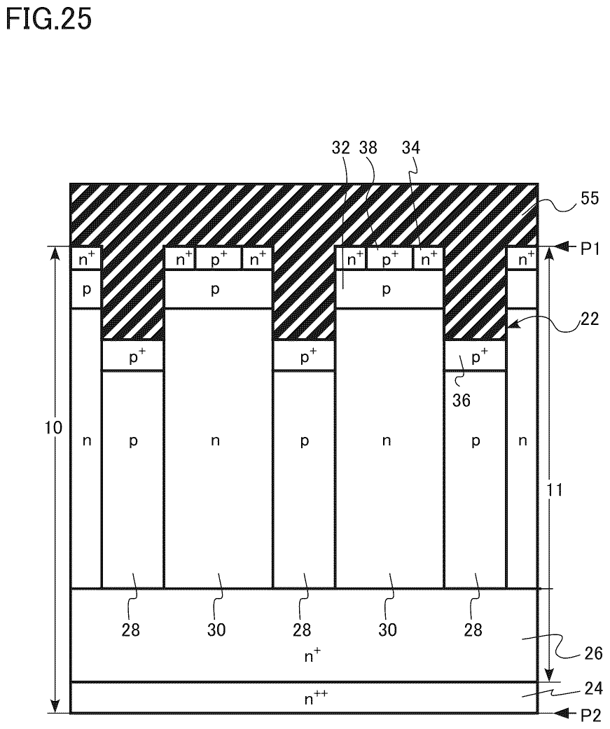

Then, an aluminum nitride layer 55 is formed on the surface of the nitride semiconductor layer 10 (FIG. 25). The aluminum nitride layer 55 is an example of a covering layer.

Then, activation annealing is performed. The activation annealing is performed at a temperature equal to or more than 900° C. and equal to or less than 1200° C., for example. The activation annealing is performed, for example, in a hydrogen gas atmosphere. The atmosphere for the activation annealing is not limited to the hydrogen gas atmosphere. For example, the activation annealing is performed in a non-oxidizing atmosphere containing argon, nitrogen, or helium.

The activation annealing is an example of the third heat treatment. The temperature of the activation annealing is the third temperature. The third temperature is, for example, higher than the first temperature of the first heat treatment and the second temperature of the second heat treatment.

By the activation annealing, ion-implanted carbon (C) enters the nitrogen sites of the gallium nitride to become electrically activated. The electrically activated carbon functions as a p-type impurity. The activated carbon functions as an acceptor.

For example, at least a part of the carbon enters the nitrogen sites of the gallium nitride as hydrogen-bonded carbon. By forming hydrogen-bonded carbon, carbon more readily enters the nitrogen sites of the gallium nitride. When carbon has entered the nitrogen sites of the gallium nitride as hydrogen-bonded carbon, the carbon is electrically inactive.

In addition, the activation annealing causes the ion-implanted nitrogen (N) to fill the nitrogen vacancies formed by the ion implantation of hydrogen (H).

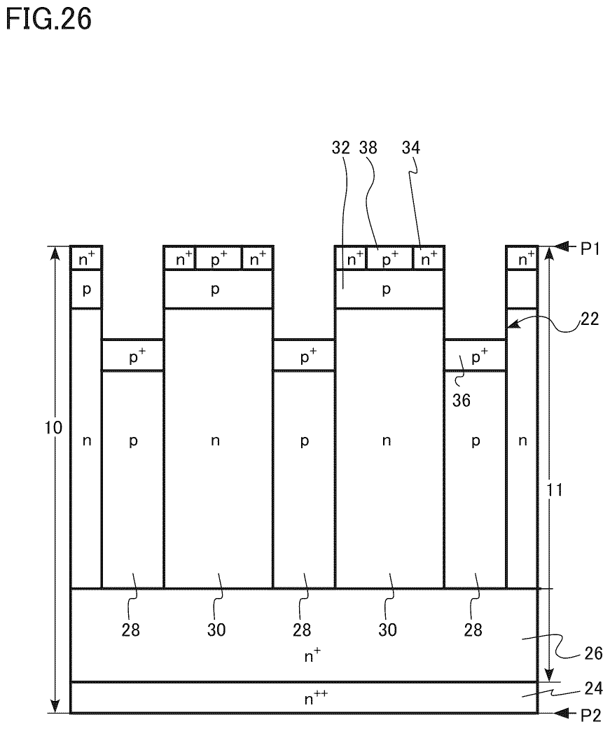

Then, the aluminum nitride layer 55 on the surface of the nitride semiconductor layer 10 is removed by using a known wet etching method (FIG. 26). The surface of the nitride semiconductor layer 10 is exposed.

Then, hydrogen desorption annealing is performed. The hydrogen desorption annealing is performed at a temperature equal to or more than 300° C. and equal to or less than 900° C., for example. The hydrogen desorption annealing is performed, for example, in a nitrogen gas atmosphere. The hydrogen desorption annealing is performed in a non-oxidizing atmosphere containing argon, nitrogen, or helium, for example. The hydrogen desorption annealing is performed, for example, in a hydrogen-free atmosphere.

Since the aluminum nitride layer 55 has been removed, outward diffusion of hydrogen from the nitride semiconductor layer 10 is promoted during the hydrogen desorption annealing.

By the hydrogen desorption annealing, the hydrogen of the hydrogen-bonded carbon that has entered the nitrogen sites of the gallium nitride is separated from the carbon, and only the carbon is left in the nitrogen sites to become electrically activated. The electrically activated carbon functions as a p-type impurity. The activated carbon functions as an acceptor.

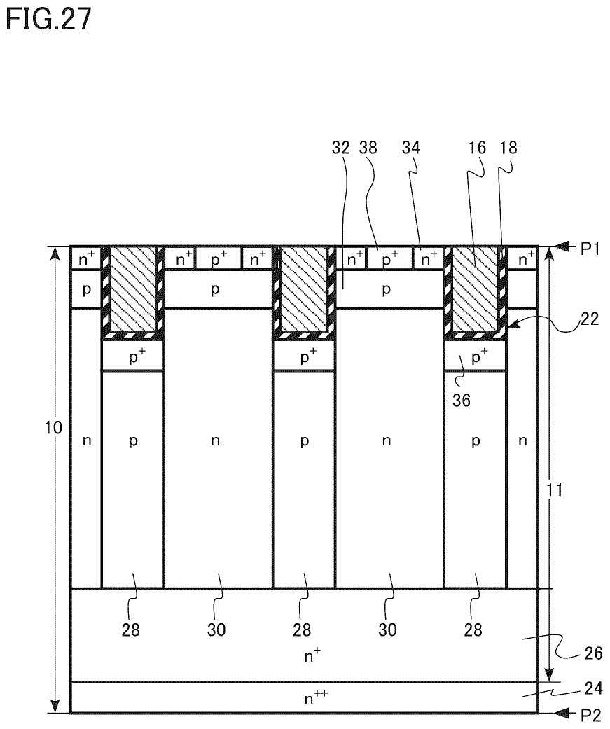

Then, the gate insulating layer 18 and the gate electrode 16 are formed in the gate trench 22 by using a known process technique (FIG. 27).

Then, the interlayer insulating layer 20, the source electrode 12, and the drain electrode 14 are formed by using a known process technique. By the manufacturing method described above, the MOSFET 200 shown in FIG. 13 is manufactured.

Since the MOSFET 200 has a trench gate structure, it is possible to reduce the on-resistance per unit area compared with the MOSFET 100 having a planar gate structure, for example.

In addition, the MOSFET 200 has an SJ structure formed by the p-pillar region 28 and the n-pillar region 30. Therefore, according to the MOSFET 200, it is possible to realize a high breakdown voltage and low on-resistance.

In the MOSFET 200, the nitrogen vacancy level density of the p-pillar region 28, which is measured by deep level transient spectroscopy (DLTS), is lower than the nitrogen vacancy level density of the n-pillar region 30 measured by DLTS. Therefore, in the MOSFET 200, the density of nitrogen vacancies in the p-pillar region 28 is lower than the density of nitrogen vacancies in the n-pillar region 30. Therefore, the balance between temporal changes in the depletion layer width of the p-pillar region 28 and the depletion layer width of the n-pillar region 30 is maintained. As a result, a high breakdown voltage of the MOSFET 200 can be realized.

In addition, the nitrogen vacancies present in the nitride semiconductor function as n-type impurities, that is, donors. In the MOSFET 200, since the density of nitrogen vacancies in the p-pillar region 28 is lower than the density of nitrogen vacancies in the n-pillar region 30, the concentration of electrically active p-type impurities in the p-pillar region 28 can be increased.

In addition, in the semiconductor device manufacturing method according to the second embodiment, as in the semiconductor device manufacturing method according to the first embodiment, after a deep p-type region is formed, nitrogen (N) is ion-implanted. Thereafter, nitrogen (N) is diffused by the second heat treatment. By diffusing nitrogen (N), nitrogen vacancies are filled with nitrogen (N), reducing the density of nitrogen vacancies in the p-pillar region 28.

Therefore, a high breakdown voltage of the MOSFET 200 can be realized. In addition, it is possible to increase the concentration of electrically active p-type impurities in the p-pillar region 28 of the MOSFET 200.

According to the semiconductor device manufacturing method according to the second embodiment, as in the semiconductor device manufacturing method according to the first embodiment, it is possible to form a deep p-type region in a nitride semiconductor layer by using a simple manufacturing method with a small number of steps.

In addition, in the semiconductor device manufacturing method according to the second embodiment, for example, the ion implantation of hydrogen (H), the ion implantation of p-type impurities, and the ion implantation of nitrogen (N) are performed using the same mask material. Therefore, since the alignment of the mask for ion implantation is not necessary, scaling-down of the MOSFET can be realized.

In addition, since the semiconductor device manufacturing method according to the second embodiment does not depend on channeling ion implantation, it is possible to form a p-type region with the same depth regardless of the crystal orientation of the surface of the nitride semiconductor layer 10. Therefore, according to the semiconductor device manufacturing method according to the second embodiment, it is possible to suppress variations in the depth of the p-type region.

As described above, according to the second embodiment, it is possible to realize a semiconductor device with a high breakdown voltage. In addition, according to the second embodiment, it is possible to realize a semiconductor device manufacturing method capable of easily forming a deep p-type region.

In the first and second embodiments, the planar gate type vertical MOSFET or the trench gate type vertical MOSFET has been described as an example of the semiconductor device. However, embodiments can also be applied to other vertical semiconductor devices. For example, embodiments can also be applied to a planar gate type vertical high electron mobility transistor (HEMT) or a trench gate type vertical HEMT.

While certain embodiments have been described, these embodiments have been presented by way of example only, and are not intended to limit the scope of the inventions. Indeed, the semiconductor device manufacturing method and the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device manufacturing method, comprising:
forming a mask material on a surface of a nitride semiconductor layer including a first n-type region, the mask material having a plurality of openings repeatedly arranged in a first direction parallel to the surface and extending in a second direction parallel to the surface and perpendicular to the first direction;
performing first processing for implanting at least one substance selected from a group consisting of hydrogen (H), helium (He), and electrons into a first region of the nitride semiconductor layer by using the mask material as a mask;
performing a first ion implantation for implanting p-type impurities into a second region shallower than the first region by using the mask material as a mask, after the performing the first processing;
performing a first heat treatment at a first temperature simultaneously with the performing the first ion implantation or after the performing the first ion implantation;
performing a second ion implantation for implanting nitrogen (N) into the nitride semiconductor layer by using the mask material as a mask, after the performing the first heat treatment; and
performing a second heat treatment at a second temperature simultaneously with the second ion implantation or after the performing the second ion implantation.

2. The semiconductor device manufacturing method according to claim 1,
wherein the p-type impurity is carbon (C) or magnesium (Mg).

3. The semiconductor device manufacturing method according to claim 1,
wherein a depth of the first region is equal to or more than 5 μm.

4. The semiconductor device manufacturing method according to claim 1,
wherein the nitride semiconductor layer further includes a second n-type region having an n-type impurity concentration higher than that of the first n-type region,
the first n-type region is provided between the second n-type region and the surface,
the first n-type region is in contact with the second n-type region, and
the first region is in contact with the second n-type region.

5. The semiconductor device manufacturing method according to claim 1,
wherein a depth of the first region is equal to or more than three times a depth of the second region.

6. The semiconductor device manufacturing method according to claim 1, further comprising:
removing the mask material after the performing the second heat treatment; and
performing a third heat treatment at a third temperature higher than the first temperature and the second temperature, after the removing the mask material.

7. The semiconductor device manufacturing method according to claim 6, further comprising:
forming a covering layer on the surface of the nitride semiconductor layer, before the performing the third heat treatment and after the removing the mask material;
removing the covering layer, after the performing the third heat treatment; and
performing a fourth heat treatment at a fourth temperature lower than the third temperature, after the removing the covering layer.

8. The semiconductor device manufacturing method according to claim 7,
wherein the first temperature is equal to or more than 300° C. and equal to or less than 1000° C., the second temperature is equal to or more than 300° C. and equal to or less than 1000° C., the third temperature is equal to or more than 900° C. and equal to or less than 1200° C., and the fourth temperature is equal to or more than 300° C. and equal to or less than 900° C.

9. The semiconductor device manufacturing method according to claim 1,
wherein, in the first processing, hydrogen (H) is ion-implanted at a temperature equal to or more than 300° C.

10. The semiconductor device manufacturing method according to claim 1, further comprising:
performing a third ion implantation for implanting hydrogen (H) into the nitride semiconductor layer by using the mask material as a mask, after the performing the first processing and before the performing the first heat treatment,
wherein the substance is helium (He) or an electron.

11. The semiconductor device manufacturing method according to claim 1,
wherein the mask material includes a metal film.

12. The semiconductor device manufacturing method according to claim 1, further comprising:
forming a trench in the nitride semiconductor layer by using the mask material as a mask, before the performing the first processing.

13. A semiconductor device, comprising:
a first electrode;
a second electrode;
a nitride semiconductor layer provided between the first electrode and the second electrode, the nitride semiconductor layer having a first face and a second face, the first face being parallel to a first direction and a second direction perpendicular to the first direction, and the second face being parallel to the first direction and the second direction and facing the first face, and the nitride semiconductor layer including;
a first nitride semiconductor region of p-type and a second nitride semiconductor region of n-type arranged alternately in the first direction;
a third nitride semiconductor region of p-type provided between the second nitride semiconductor region and the first face; and
a fourth nitride semiconductor region of n-type provided between the third nitride semiconductor region and the first face;
a gate electrode provided on a first face side of the nitride semiconductor layer, facing the third nitride semiconductor region, and extending in the second direction; and
a gate insulating layer provided between the gate electrode and the nitride semiconductor layer,
wherein a nitrogen vacancy level density of the first nitride semiconductor region measured by deep level transient spectroscopy (DLTS) is lower than a nitrogen vacancy level density of the second nitride semiconductor region measured by DLTS.

14. The semiconductor device according to claim 13,
wherein the nitride semiconductor layer further includes a trench provided on the first face side and extending in the second direction on the first face, and
the gate electrode is provided in the trench.

15. The semiconductor device according to claim 14,
wherein the first nitride semiconductor region is provided between the trench and the second face.
